(19) United States
(12) Patent Application Publication
(10) Pub. No.: US 2026/0123183 A1
(43) Pub. Date: Apr. 30, 2026

(54) ELECTRONIC APPARATUS AND METHOD FOR MANUFACTURING THE SAME

(71) Applicant: Samsung Display Co., Ltd., Yongin-si (KR)

(72) Inventors: Kyung-Tae KIM, Yongin-si (KR); Seong-Jun CHO, Yongin-si (KR); Kihwan KIM, Yongin-si (KR); Jun Hyung LIM, Yongin-si (KR); Hyunjun JEONG, Yongin-si (KR); Jongwoo JIN, Yongin-si (KR)

(73) Assignee: Samsung Display Co., Ltd., Yongin-si (KR)

(21) Appl. No.: 19/369,592

(22) Filed: Oct. 27, 2025

(30) Foreign Application Priority Data
Oct. 25, 2024 (KR) 10-2024-0147244
Sep. 14, 2025 (KR) 10-2025-0113210

(51) Int. Cl. H10K 59/121; H10D 86/40; H10K 59/12

(52) U.S. Cl. CPC H10K 59/1213; H10D 86/423; H10K 59/1201

(57) ABSTRACT

An electronic apparatus includes a circuit element layer including a scan driver and a pixel driver, and a display element layer including a light emitting element connected to the pixel driver. The circuit element layer includes a first transistor included in the pixel driver, a second transistor included in the scan driver, and an insulating layer disposed between a first oxide semiconductor layer of the first transistor and a first gate of the first transistor. The insulating layer includes a lower oxide layer, an upper oxide layer disposed on the lower oxide layer, and a nitride layer disposed between the lower oxide layer and the upper oxide layer and having a higher hydrogen concentration than the upper oxide layer.

### CROSS-REFERENCE TO RELATED APPLICATIONS

This U.S. non-provisional patent application claims priority under 35 U.S.C. § 119 of Korean Patent Application No. 10-2024-0147244, filed on Oct. 25, 2024, the entire contents of which are hereby incorporated by reference.

### BACKGROUND

Example embodiments of the present disclosure relate to an electronic apparatus and a method for manufacturing the same, and more particularly, to a display panel with improved display characteristics, and a method for manufacturing the same.

Multimedia electronic apparatuses such as televisions, mobile phones, tablet computers, navigation devices, and game consoles, may include display devices for displaying images. A display device may include a plurality of pixels, and each of the pixels may include a light emitting element which generates light, and a driving element connected to the light emitting element.

Display devices including organic light emitting elements among light emitting elements receive attention as next-generation display devices due to improvements such as wide viewing angles, fast response speeds, and lower power consumption. However, as the display devices are improved in large surface area and high resolution, driving elements with improved characteristics are desired.

### SUMMARY

A display panel may include a pixel including a light emitting element and a pixel driver which drives the light emitting element, and a driver which drives pixels. The driver may include a scan driver and a data driver. The scan driver may be provided as being mounted together with the pixels on a substrate.

An electronic apparatus according to an embodiment of the present disclosure includes a substrate, a circuit element layer on the substrate, the circuit element layer comprising a scan driver and a pixel driver, and a display element layer on the circuit element layer, the display element layer comprising a light emitting element connected to the pixel driver. The circuit element layer comprises a first transistor in the pixel driver, the first transistor comprising a first oxide semiconductor layer and a first gate, a second transistor in the scan driver, the second transistor comprising a second gate and a second oxide semiconductor layer, and the second oxide semiconductor layer at a level different from a level of the first oxide semiconductor layer, and an insulating layer between the first oxide semiconductor layer and the first gate. The insulating layer comprises a lower oxide layer, an upper oxide layer on the lower oxide layer, and a nitride layer between the lower oxide layer and the upper oxide layer. A hydrogen concentration of the nitride layer is higher than a hydrogen concentration of the upper oxide layer.

An electronic apparatus according to an embodiment of the present disclosure includes a display panel, a processor configured to output data to the display panel, and a power module configured to supply power to the processor. The display panel comprises a light emitting element, a pixel driver connected to the light emitting element, the pixel driver comprising a first transistor, a scan driver comprising a second transistor, a gate line connecting the pixel driver to the scan driver, a data line connected to the pixel driver, the data line insulated from and intersecting the gate line, and a plurality of insulating layers. The plurality of insulating layers comprises a first insulating layer below a first semiconductor layer of the first transistor, and a second insulating layer between the first semiconductor layer and a first gate of the first transistor. Each of the first insulating layer and the second insulating layer comprises a lower oxide layer, an upper oxide layer on the lower oxide layer, and a nitride layer between the lower oxide layer and the upper oxide layer.

A method for manufacturing an electronic apparatus according to an embodiment of the present disclosure includes forming a plurality of lower conductive patterns on a substrate, stacking a first lower oxide layer, a first nitride layer, and a first upper oxide layer in sequence on the plurality of lower conductive patterns to form a first insulating layer, forming a first semiconductor layer on the first insulating layer, stacking a second lower oxide layer, a second nitride layer, and a second upper oxide layer in sequence on the first insulating layer to form a second insulating layer, forming a second semiconductor layer on the second insulating layer, forming a first gate overlapping the first semiconductor layer and a second gate overlapping the second semiconductor layer, forming a third insulating layer covering the first gate and the second gate, and forming a plurality of connection electrodes on the third insulating layer.

### BRIEF DESCRIPTION OF THE FIGURES

FIG. 1A is a perspective view of an electronic apparatus according to an embodiment of the present disclosure.

FIG. 1B is a block diagram of an electronic apparatus according to an embodiment of the present disclosure.

FIG. 2 is a view illustrating an example of a cross-section of the electronic apparatus illustrated in FIG. 1A.

FIG. 3 is a view illustrating an example of a cross-section of a display panel illustrated in FIG. 2.

FIG. 4 is a block diagram of the electronic apparatus illustrated in FIG. 1.

FIG. 5 is an equivalent circuit diagram of one of pixels according to an embodiment of the present disclosure.

FIGS. 6A and 6B are cross-sectional views of a display panel according to an embodiment of the present disclosure.

FIGS. 7A to 7E are each a graph illustrating changes in characteristics of a semiconductor layer according to a thickness of an insulating layer according to an embodiment of the present disclosure.

FIGS. 8A to 8I are cross-sectional views illustrating a method for manufacturing a display panel according to an embodiment of the present disclosure.

FIG. 9 is a block diagram of an electronic apparatus according to an embodiment of the present disclosure.

FIG. 10 is a schematic view of electronic apparatuses according to various embodiments of the present disclosure.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference symbols refer to like elements throughout. In the drawings, the thickness, ratio, and size of the elements are exaggerated for effectively describing the technical contents.

The term “and/or” includes any and all combinations of one or more of the associated listed elements.

It will be understood that, although the terms such as first and second may be used herein to describe various elements, the elements are not to be limited by these terms. These terms are only used to distinguish one element from another element. For instance, a first element could be termed a second element without departing from the scope of the present disclosure. Similarly, a second element could be termed a first element. The singular expressions are intended to include the plural forms as well, unless the context clearly indicates otherwise.

In addition, the terms “below”, “on the lower side”, “above”, “on the upper side”, or the like are used to describe the relationships between the elements illustrated in the drawings. These terms are relative concepts and are described on the basis of the directions indicated in the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprises”, “has”, or the like, when used in this specification, specify the presence of stated features, numbers, steps, operations, elements, components or combinations thereof, but do not preclude the possibility of the presence or addition of one or more other features, numbers, steps, operations, elements, components, or combinations thereof.

Hereinafter, embodiments of the present disclosure will be described with reference to the accompanying drawings.

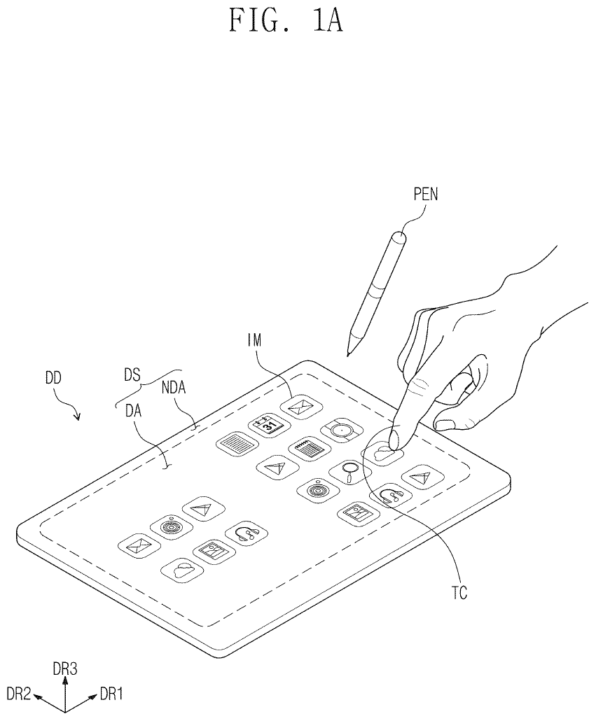

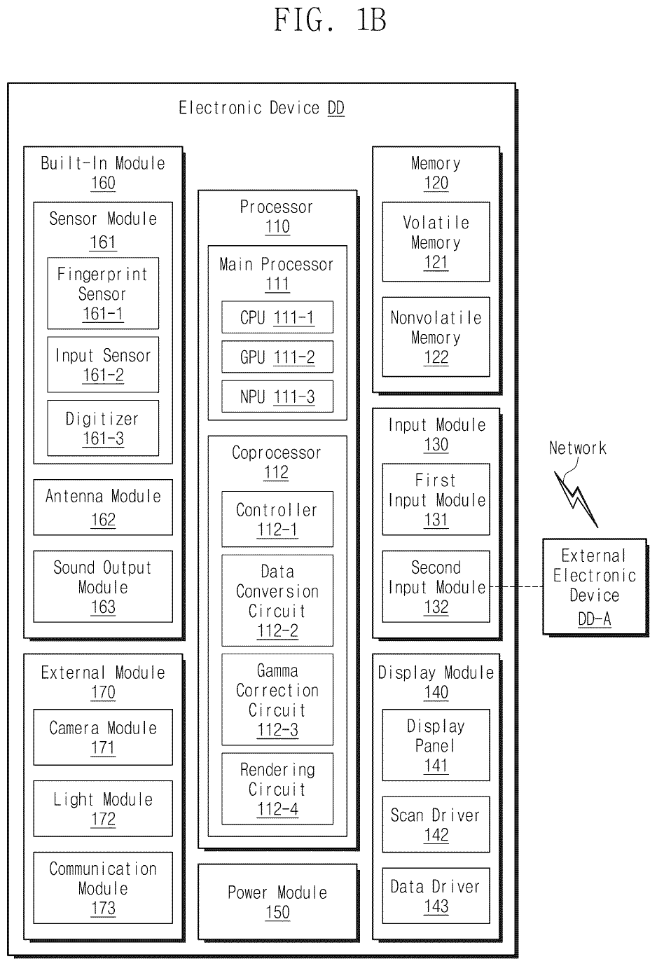

FIG. 1A is a perspective view of an electronic apparatus according to an embodiment of the present disclosure. FIG. 1B is a block diagram of an electronic apparatus according to an embodiment of the present disclosure. The present disclosure will be described with reference to FIGS. 1A and 1B.

As illustrated in FIG. 1A, an electronic apparatus DD may include long sides extending to be parallel to a first direction DR1 and short sides extending to be parallel to a second direction DR2 crossing the first direction DR1. However, this is illustrated as an example, and the electronic apparatus DD may include sides having the same length in each of the first direction DR1 and the second direction DR2, and is not limited to any one embodiment.

Hereinafter, a direction substantially perpendicularly crossing a plane defined by the first direction DR1 and the second direction DR2 is defined as a third direction DR3. In addition, in the specification, the meaning of when viewed on a plane is defined as being in a state when viewed in the third direction DR3.

A front surface of the electronic apparatus DD may be defined as a display surface DS, and may have a plane defined by the first direction DR1 and the second direction DR2. Images IM generated in the electronic apparatus DD may be provided for a user through the display surface DS.

The display surface DS may include a display area DA and a non-display area NDA around the display area DA. The display area DA may be an area on which an image is displayed, and the non-display area NDA may be an area on which an image is not displayed. The non-display area NDA may be adjacent to at least one side of the display area DA. In this embodiment, the non-display area NDA may have a frame shape surrounding the display area DA. However, this is illustrated as an example. In another electronic apparatus DD according to an embodiment of the present disclosure, the non-display area NDA may be omitted, and here, the display surface DS may include only the display area DA.

The electronic apparatus DD may detect inputs applied from the outside of the electronic apparatus DD. For example, the electronic apparatus DD may detect a first input by a touch TC and a second input by a touch pen PEN. The first input by the touch TC may include various types of external inputs such as part of a user's body, light, heat, or pressure. The touch pen PEN may be an active pen or an electromagnetic pen. The touch pen PEN includes an active pen, a passive pen, an electromagnetic pen, and the like, and is not limited to any one embodiment. The touch pen PEN may be defined as an input device, and besides displaying an image, the display area DA may provide a user with a sensing area which may sense the inputs.

Referring to FIG. 1B, an electronic apparatus DD outputs various information through a display module 140 in an operating system. When a processor 110 executes an application stored in a memory 120, the display module 140 provides application information for a user through a display panel 141.

Any or all of the elements described with reference to FIG. 1B may communicate with any or all other elements described with reference to FIG. 1B. For example, any element may engage in one-way and/or two-way and/or broadcast communication with any or all other elements in FIG. 1B, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

The processor 110 obtains an external input through an input module 130 or sensor module 161, and executes an application corresponding to the external input. For example, when the user selects a camera icon displayed on the display panel 141, the processor 110 obtains a user input through an input sensor 161-2 and activates a camera module 171. The processor 110 transmits, to the display module DM, image data corresponding to a photographic image obtained through the camera module 171. The display module 140 may display an image corresponding to the photographing image through the display panel 141.

In the above, the operations of the electronic apparatus DD are briefly described. Hereinafter, components of the electronic apparatus DD will be described in detail. Among the components of the electronic apparatus DD to be described later, some components may be integrally provided as one component, and one component may be provided as being divided into two or more components.

Referring to FIG. 1B, the electronic apparatus DD may communicate with an external electronic apparatus DD-A over a network (e.g., a short-range wireless communication network or a long-range wireless communication network). According to an embodiment, the electronic apparatus DD may include the processor 110, the memory 120, the input module 130, the display module 140, a power module 150, a built-in module 160, and an external module 170. However, example embodiments are not limited thereto. According to an embodiment, in the electronic apparatus DD, at least one of the foregoing components may be omitted, or one or more other components may be added. According to an embodiment, some components (e.g., the sensor module 161, an antenna module 162, or a sound output module 163) of the foregoing components may be integrated into another component (e.g., the display module 140).

The processor 110 may execute software to control at least one other component (e.g., a hardware or software component) of the electronic apparatus DD, connected to the processor 110, and may perform various data processing or computation. According to an embodiment, as at least a part of the data processing or computation, the processor 110 may store a command or data received from other component (e.g., the input module 130, the sensor module 161, or a communication module 173) in a volatile memory 121, process the command or data stored in the volatile memory 121, and store the resulting data in a nonvolatile memory 122.

The processor 110 may include a main processor 111 and a coprocessor 112. The main processor 111 may include at least one of a central processing unit (CPU) 111-1 or an application processor (AP). The main processor 111 may further include at least one of a graphic processing unit (GPU) 111-2, a communication processor (CP), or an image signal processor (ISP). The main processor 111 may further include a neural processing unit (NPU) 111-3. The neural processing unit may be a processor specialized for processing of an artificial intelligence model, and the artificial intelligence model may be created through machine learning. The artificial intelligence model may include a plurality of artificial neural network layers. The artificial neural network may be one of deep neural network (DNN), convolutional neural network (CNN), recurrent neural network (RNN), restricted boltzmann machine (RBM), deep belief network (DBN), bidirectional recurrent deep neural network (BRDNN), deep Q-networks, or a combination of two or more of the foregoing networks, but example embodiments are not limited to the foregoing examples. The artificial intelligence model may additionally or alternatively include a software structure in addition to a hardware structure. At least two of the foregoing processing units and processors may be implemented as one integrated component (e.g., a single chip), or the foregoing processing units and processors may be implemented as independent components (e.g., a plurality of chips).

The coprocessor 112 may include a controller 112-1. The controller 112-1 may include an interface conversion circuit and a timing control circuit. The controller 112-1 receives an image signal from the main processor 111 and outputs image data obtained by converting a data format of the image signal so as to be suitable for the specification of an interface with the display module 140. The controller 112-1 may output various control signals necessary for driving the display module DM.

The coprocessor 112 may further include a data conversion circuit 112-2, a gamma correction circuit 112-3, a rendering circuit 112-4, or the like. The data conversion circuit 112-2 may receive image data from the controller 112-1, and compensate for the image data such that an image is displayed with a desired luminance according to characteristics of the electronic apparatus DD or user settings, or convert the image data to reduce power consumption or compensate for image-sticking. The gamma correction circuit 112-3 may convert image data, a gamma reference voltage, or the like such that an image displayed on the electronic apparatus DD has a desired gamma characteristic. The rendering circuit 112-4 may receive the image data from the controller 112-1, and render the image data in consideration of a pixel arrangement of the display panel 141 applied to the electronic apparatus DD, or the like. At least one of the data conversion circuit 112-2, the gamma correction circuit 112-3, or the rendering circuit 112-4 may be integrated into other component (e.g., the main processor 111 or the controller 112-1). At least one of the data conversion circuit 112-2, the gamma correction circuit 112-3, or the rendering circuit 112-4 may be integrated into a data driver 143 to be described later.

The memory 120 may store various data used by at least one component (e.g., the processor 110 or the sensor module 161) of the electronic apparatus DD, and input data or output data for relevant commands. The memory 120 may include at least one of the volatile memory 121 or the nonvolatile memory 122.

The input module 130 may receive a command or data to be used in a component (e.g., the processor 110, the sensor module 161, or the sound output module 163) of the electronic apparatus DD from the outside (e.g., the user or the external electronic apparatus 102) of the electronic apparatus DD-A.

The input module 130 may include a first input module 131 to which a command or data is input from the user, and a second input module 132 to which a command or data is input from the external electronic apparatus DD-A. The first input module 131 may include a microphone, a mouse, a keyboard, a key (e.g., a button), or a pen (e.g., a passive pen or an active pen). The second input module 132 may support a designated protocol capable of being connected to the external electronic apparatus DD-A in a wired or wireless manner. According to an embodiment, the second input module 132 may include a high definition multimedia interface (HDMI), a universal serial bus (USB) interface, a secure digital (SD) card interface, or an audio interface. The second input module 132 may include a connector capable of being physically connected to the external electronic apparatus DD-A, for example, an HDMI connector, a USB connector, an SD card connector, or an audio connector (e.g., a headphone connector). However, example embodiments are not limited thereto.

The display module 140 visually provides information for the user. The display module 140 may include the display panel 141, a scan driver 142 and the data driver 143. The display module DM may further include a window, a chassis, and a bracket for protecting the display panel 141. However, example embodiments are not limited thereto.

The display panel 141 may include a liquid crystal display panel, an organic light emitting display panel, or an inorganic light emitting display panel, and the type of the display panel 141 is not particularly limited. The display panel 141 may be a rigid type, or a flexible type capable of being rolled or folded. The display module 140 may further include a supporter which supports the display panel 141, a bracket, a heat dissipation member, or the like. However, example embodiments are not limited thereto.

The scan driver 142 may be a driving chip and mounted on the display panel 141. Alternatively, the scan driver 142 may be integrated into the display panel 141. For example, the scan driver 142 may include an amorphous silicon TFT gate driver circuit (ASG), a low temperature polycrystalline silicon (LTPS) TFT gate driver circuit, or an oxide semiconductor TFT gate driver circuit (OSG), internalized into the display panel 141. The scan driver 142 receives a control signal from the controller 112-1, and outputs gate signals to the display panel 141 in response to the control signal.

The display panel 141 may further include an emission driver. The emission driver outputs an emission control signal to the display panel 141 in response to the control signal received from the controller 112-1. The emission driver may be separated from the scan driver 142, or be integrated into the scan driver 142.

The data driver 143 receives the control signal from the controller 112-1, and converts image data into analog voltages (e.g., data voltages) in response to the control signal and then outputs the data voltages to the display panel 141.

The data driver 143 may be incorporated into another component (e.g., the controller 112-1), but example embodiments are not limited thereto. The functions of the interface conversion circuit and the timing control circuit of the controller 112-1 described above may be incorporated into the data driver 143.

The display module 140 may further include the emission driver, a voltage generation circuit, and the like, but example embodiments are not limited thereto. The voltage generating circuit may output various voltages necessary for driving of the display panel 141.

The power module 150 supplies power to the components of the electronic apparatus DD. The power module 150 may include a battery which charges a power voltage. The battery may include a non-rechargeable primary battery, a rechargeable secondary battery, or a fuel battery, but example embodiments are not limited thereto. The power module 150 may include a power management integrated circuit (PMIC). The PMIC supplies optimized power to each of the modules described above and modules to be described later. The power module 150 may include a wireless power transmission/reception member electrically connected to the battery. The wireless power transmission/reception member may include a plurality of antenna radiators in the form of coils.

The electronic apparatus DD may further include the built-in module 160 and the external module 170. The built-in module 160 may include the sensor module 161, the antenna module 162, and the sound output module 163, but example embodiments are not limited thereto. The external module 170 may include the camera module 171, a light module 172, and the communication module 173.

The sensor module 161 may detect an input by the user's body or an input by a pen of the first input module 131, and generate an electrical signal or data value corresponding to the input. The sensor module 161 may include at least one of a fingerprint sensor 161-1, the input sensor 161-2, or a digitizer 161-3. However, example embodiments are not limited thereto.

The fingerprint sensor 161-1 may generate a data value corresponding to the user's fingerprint. The fingerprint sensor 161-1 may include one of an optical or capacitance fingerprint sensor.

The input sensor 161-2 may generate a data value corresponding to coordinate information of an input by the user's body or an input by a pen. The input sensor 161-2 generates a capacitance change due to the input as a data value. The input sensor 161-2 may detect an input by the passive pen or transmit/receive data to/from the active pen.

The input sensor 161-2 may measure a bio-signal such as blood pressure, moisture, or body fat. For example, when the user touches part of the body to a sensor layer or a sensing panel and does not move for a certain period of time, the input sensor 161-2 may detect a bio-signal and output information desired by the user to the display module 140 on the basis of a change in electric field caused by the part of the body.

The digitizer 161-3 may generate a data value corresponding to coordinate information of an input by the pen. The digitizer 161-3 generates an electromagnetic change by the input as a data value. The digitizer 161-3 may detect an input by the passive pen or transmit/receive data to/from the active pen.

At least one of the fingerprint sensor 161-1, the input sensor 161-2, or the digitizer 161-3 may be implemented as a sensor layer formed on the display panel 141 through a continuous process. The fingerprint sensor 161-1, the input sensor 161-2, and the digitizer 161-3 may be disposed above the display panel 141, and one of the fingerprint sensor 161-1, the input sensor 161-2, and the digitizer 161-3, for example, the digitizer 161-3, may be disposed below the display panel 141.

At least two of the fingerprint sensor 161-1, the input sensor 161-2, and the digitizer 161-3 may be integrated into one sensing panel through the same process. When the at least two are integrated into the one sensing panel, the sensing panel may be disposed between the display panel 141 and a window disposed above the display panel 141. According to an embodiment, the sensing panel may be disposed on the window, and a position of the sensing panel is not particularly limited.

At least one of the fingerprint sensor 161-1, the input sensor 161-2, or the digitizer 161-3 may be built in the display panel 141. That is, at least one of the fingerprint sensor 161-1, the input sensor 161-2, or the digitizer 161-3 may be simultaneously formed through a process of forming elements (e.g., light emitting elements, transistors, or the like) included in the display panel 141.

In addition, the sensor module 161 may generate an electrical signal or a data value corresponding to an internal state or external state of the electronic apparatus DD. The sensor module 161 may further include, for example, a gesture sensor, a gyro sensor, a barometric pressure sensor, a magnetic sensor, an acceleration sensor, a grip sensor, a proximity sensor, a color sensor, an IR (infrared) sensor, a biosensor, a temperature sensor, a humidity sensor, or an illuminance sensor.

The antenna module 162 may include one or more antennas for transmitting a signal or power to the outside or receiving a signal or power from the outside. According to an embodiment, the communication module 173 may transmit a signal to an external electronic apparatus or receive a signal from the external electronic apparatus through an antenna suitable for a communication method. An antenna pattern of the antenna module 162 may be integrated into one component (e.g., the display panel 141) of the display module DM, the input sensor 161-2, or the like.

The sound output module 163 may be a device for outputting a sound signal to the outside of the electronic apparatus DD, and include, for example, a speaker used for general purposes such as multimedia playback or recording playback and a receiver used exclusively for receiving calls. According to an embodiment, the receiver may be formed integrally with or separately from the speaker. A sound output pattern of the sound output module 163 may be integrated into the display module 140.

The camera module 171 may photograph still images and moving images. According to an embodiment, the camera module 171 may include one or more lenses, image sensors, or image signal processors, but example embodiments are not limited thereto. The camera module 171 may further include an infrared camera capable of measuring the presence/absence of a user, the user's position, the user's gaze, or the like.

The light module 172 may provide light. The light module 172 may include a light emitting diode or a xenon lamp. The light module 172 may operate in conjunction with the camera module 171 or operate independently.

The communication module 173 may establish a wired or wireless communication channel between the electronic apparatus DD and the external electronic apparatus DD-A, and support communication through the established communication channel. The communication module 173 may include one or all of a wireless communication module such as a cellular communication module, a short-range wireless communication module, or a global navigation satellite system (GNSS) communication module, and a wired communication module such as a local area network (LAN) communication module or a power line communication module, but example embodiments are not limited thereto. The communication module 173 may communicate with the external electronic apparatus DD-A through a short-range communication network such as Bluetooth, WiFi direct, or infrared data association (IrDA), or a long-range communication network such as cellular network, Internet, or computer network (e.g., LAN or WAN). The foregoing various types of communication modules 173 may be implemented as a single chip, or implemented as separate chips, respectively.

The input module 130, the sensor module 161, the camera module 171, and the like may be utilized to control the operation of the display module 140 in conjunction with the processor 110.

The processor 1110 outputs a command or data to the display module 140, the sound output module 163, the camera module 171, or the light module 172, based on input data received from the input module 130. For example, the processor 110 may generate image data in response to the input data input through a mouse, an active pen, or the like, and output the image data to the display module 140, or may generate command data in response to the input data and output the command data to the camera module 171 or the light module 172. When the input data is not received from the input module 130 for a certain period of time, the processor 110 may convert an operation mode of the electronic apparatus DD into a low power mode or a sleep mode, thereby reducing power consumed by the electronic apparatus DD.

The processor 110 outputs a command or data to the display module 140, the sound output module 163, the camera module 171, or the light module 172, based on sensing data received from the sensor module 161. For example, the processor 110 may compare authentication data input by the fingerprint sensor 161-1 with authentication data stored in the memory 120 and then execute an application according to a result of the comparison. The processor 110 may execute a command, based on sensing data detected by the input sensor 161-2 or the digitizer 161-3, or output corresponding image data to the display module 140. When the sensor module 161 includes a temperature sensor, the processor 110 may receive temperature data for temperatures measured from the sensor module 161 and further perform a luminance correction, or the like on the image data, based on the temperature data.

The processor 110 may receive measurement data about the presence/absence of a user, the position of the user, the user's gaze, or the like from the camera module 171. The processor 110 may further perform the luminance correction or the like on the image data, based on the measurement data. For example, the processor 110 having determined the presence/absence of a user through an input from the camera module 171 may output, to the display module 140, image data in which the luminance is corrected through the data conversion circuit 112-2 or the gamma correction circuit 112-3.

Some of the foregoing components may be connected to each other through a communication method between peripheral devices, for example, a bus, a general purpose input/output (GPIO), a serial peripheral interface (SPI), a mobile industry processor interface (MIPI), or a ultra path interconnect (UPI) link, and exchange signals (e.g., commands or data) with each other. The processor 110 may communicate with the display module 140 through an appointed interface. For example, one of the foregoing communication methods may be used, and the communication method is not limited to the foregoing communication methods.

The electronic apparatuses DD according to various embodiments described herein may be various types of apparatuses. The electronic apparatus DD may include, for example, at least one of a portable communication device (e.g., a smartphone), a computer device, a portable multimedia device, a portable medical device, a camera, a wearable device, or a home appliance. The electronic apparatus DD according to an embodiment herein is not limited to the foregoing apparatuses.

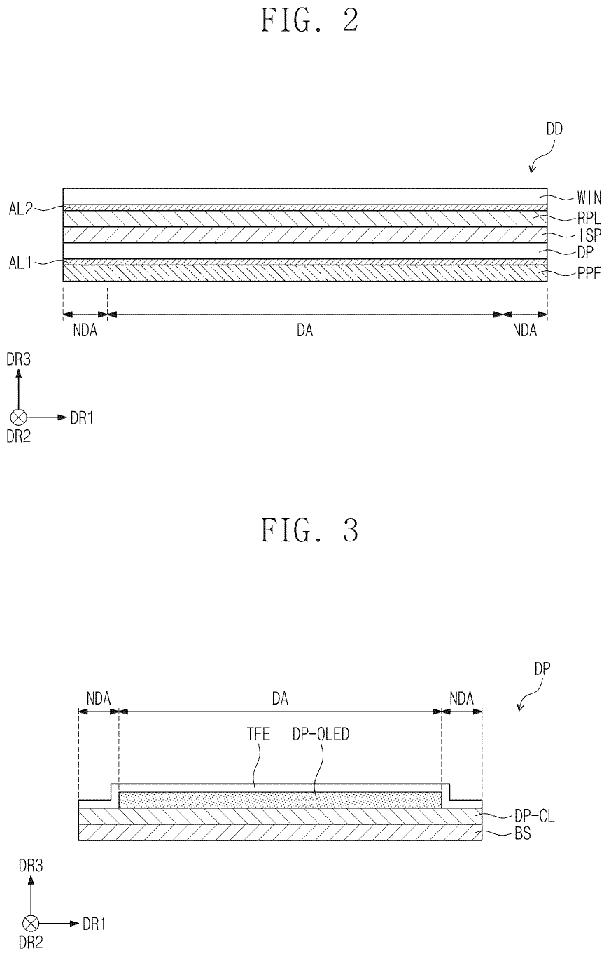

FIG. 2 is a view illustrating an example of a cross-section of the electronic apparatus illustrated in FIG. 1A. FIG. 3 is a view illustrating an example of a cross-section of a display panel illustrated in FIG. 2. The present disclosure will be described with reference to FIGS. 2 and 3.

Referring to FIG. 2, the electronic apparatus DD may include a display panel DP, an input sensing part ISP, an anti-reflective layer RPL, a window WIN, a panel protective film PPF, and first and second adhesive layers AL1 and AL2. The display panel DP may correspond to the display panel 141 (see FIG. 1B) described above, and the input sensing part ISP may correspond to the sensor module 161 (see FIG. 1B) described above.

The display panel DP according to an embodiment of the present disclosure may be an emissive display panel. For example, the display panel DP may be an organic light emitting display panel or an inorganic light emitting display panel. An emission layer of the organic light emitting display panel may include an organic light emitting material. An emission layer of the inorganic light emitting display panel may include a quantum dot, a quantum rod, or the like, but example embodiments are not limited thereto. Hereinafter, an organic light emitting display panel will be described as an example of the display panel DP.

Referring to FIG. 3, a display panel DP may include a substrate BS, a circuit element layer DP-CL, a display element layer DP-OLED, and a thin-film encapsulation layer TFE.

The circuit element layer DP-CL disposed on the substrate SUB, the display element layer DP-OLED disposed on the circuit element layer DP-CL, and the thin film encapsulation layer TFE disposed on the display element layer DP-OLED may be included.

The substrate BS may include glass, or a flexible plastic material such as polyimide (PI).

The circuit element layer DP-CL, the display element layer DP-OLED, and the thin film encapsulation layer TFE may be disposed, in sequence, on the substrate BS. A plurality of pixels may be disposed in the circuit element layer DP-CL and the display element layer DP-OLED. Each of the pixels may include a transistor disposed in the circuit element layer DP-CL, and a light emitting element disposed in the display element layer DP-OLED and connected to the transistor.

The thin-film encapsulation layer TFE may be disposed on the circuit element layer DP-CL so as to cover the display element layer DP-OLED. The thin-film encapsulation layer TFE may protect the pixels from moisture, oxygen, and external foreign matter. Meanwhile, in this embodiment, the thin-film encapsulation layer TFE is illustrated as covering the entire area of the substrate SUB, but according to an embodiment of the present disclosure, the substrate SUB may include a partial area exposed from the thin-film encapsulation layer TFE. Alternatively, the area exposed from the thin-film encapsulation layer TFE may be provided along an edge of the substrate SUB, and is not limited to any one embodiment.

The input sensing part ISP may be disposed on the display panel DP. The input sensing part ISP may include a plurality of sensors (not illustrated) for sensing an external input by using a capacitance method. The input sensor ISP may be directly formed on the display panel DP during manufacture of the electronic apparatus DD. Specifically, a conductive pattern or an insulating layer, which constitutes the input sensing part ISP, may be directly deposited or patterned on the display panel DP. However, the input sensing part ISP is not limited thereto, and the input sensing part ISP may be manufactured as a separate panel from the display panel DP to be attached to the display panel DP through an adhesive layer, and is not limited to any one embodiment.

The anti-reflective layer RPL may be disposed on the input sensing part ISP. The anti-reflective layer RPL may reduce an external light reflectance of the electronic apparatus DD, thereby improving visibility of an image displayed on the electronic apparatus DD. The anti-reflective layer RPL may include a retarder, a polarizer, a black matrix, color filters, and the like, and is not limited to any one embodiment. The anti-reflective layer RPL may be directly formed on the input sensing part ISP through a process such as coating or deposition, or be provided in the form of a film to be attached to the input sensing part ISP through an adhesive layer, and the anti-reflective layer RPL is not limited to any one embodiment.

The window WIN may be disposed on the anti-reflective layer RPL. The window WIN may protect the display panel DP, the input sensing part ISP, and the anti-reflective layer RPL from external scratches and impact.

The panel protective film PPF may be disposed below the display panel DP. The panel protective layer PPF may support the display panel DP and protect a lower portion of the display panel DP. The panel protective layer PPF may have an insulating property. For example, the panel protective layer PPF may include resin such as polyethylene terephthalate (PET), polyimide (PI), or polypropylene (PP), but example embodiments are not limited thereto.

The first adhesive layer AL1 may be disposed between the display panel DP and the panel protective film PPF, and the display panel DP and the panel protective layer film may be bonded to each other through the first adhesive layer AL1. The second adhesive layer AL2 may be disposed between the window WIN and the anti-reflective layer RPL, and the window WIN and the anti-reflective layer RPL may be bonded to each other through the second adhesive layer AL2.

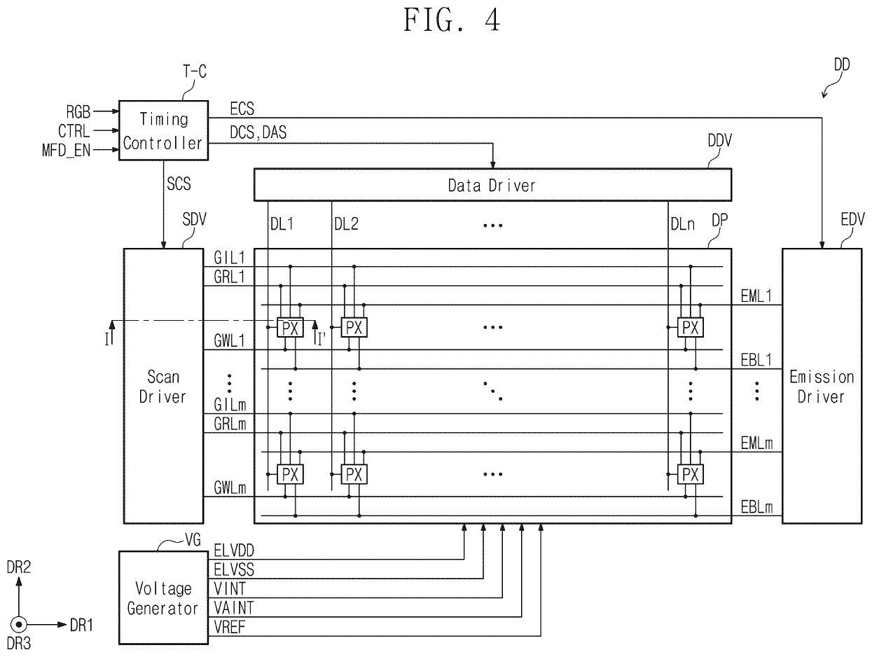

FIG. 4 is a block diagram of the electronic apparatus illustrated in FIG. 1. Referring to FIG. 4, an electronic apparatus DD may include a display panel DP, a timing controller T-C, a scan driver SDV, a data driver DDV, an emission driver EDV, and a voltage generator VG. The display panel DP, the timing controller T-C, the scan driver SDV, the data driver DDV, the emission driver EDV, and the voltage generator VG may correspond to the display panel 141 (see FIG. 1B), the processor 110 (see FIG. 1B), the scan driver 142 (see FIG. 1B), the data driver 143 (see FIG. 1B), an emission driver (not illustrated), and the power module 150 (see FIG. 1B), respectively.

The display panel DP may include a plurality of gate lines (or a plurality of scan lines) GIL1 to GILm, GWL1 to GWLm and GRL1 to GRLm, a plurality of emission lines EML1 to EMLm, a plurality of data lines DL1 to DLn, and a plurality of pixels PX, wherein m and n are each a natural number.

The pixels PX may be electrically connected to the gate lines GIL1 to GILm, GWL1 to GWLm and GRL1 to GRLm, the emission lines EML1 to EMLm, and the data lines DL1 to DLn, respectively. Each of the pixels PX may be electrically connected to four corresponding gate lines, one corresponding data line, and one corresponding emission line.

The gate lines GIL1 to GILm, GWL1 to GWLm and GRL1 to GRLm may include a plurality of initialization gate lines GIL1 to GILm, a plurality of write gate lines GWL1 to GWLm, and a plurality of reset gate lines GRL1 to GRLm.

Each of the pixels PX may be connected to a corresponding one of the initialization gate lines GIL1 to GILm, a corresponding one of the write gate lines GWL1 to GWLm, and a corresponding one of the reset gate lines GRL1 to GRLm.

The gate lines GIL1 to GILm, GWL1 to GWLm and GRL1 to GRLm may be connected to the scan driver SDV and extend in the first direction DR1 to be arranged in the second direction DR2. The emission lines EML1 to EMLm may be connected to the emission driver EDV and extend in the first direction DR1 to be arranged in the second direction DR2. In this embodiment, the scan driver SDV and the emission driver EDV may be arranged to be spaced apart from each other with the pixels PX therebetween. However, this is illustrated as an example, and the scan driver SDV and the emission driver EDV may be disposed at the same side with respect to the pixels PX, and may be provided as one body constituting one driver. Alternatively, each of the scan driver SDV and the emission driver EDV may include a plurality of divided drivers, and is not limited to any one embodiment.

Meanwhile, in this embodiment, the scan driver SDV may be provided as being formed in the display panel DP. That is, the scan driver SDV and the pixels PX may be disposed on the same substrate and provided to one display panel DP.

The data lines DL1 to DLn may be connected to the data driver DDV and extend in the second direction DR2 to be arranged in the first direction DR1. In this embodiment, the emission driver EDV and the data driver DDV may be substantially disposed in the display panel DP. However, this is illustrated as an example and example embodiments are not limited thereto. At least one of the emission driver EDV and the data driver DDV may be provided to a separate circuit board and electrically connected to the display panel DP so as to provide an electrical signal to the pixels PX, and is not limited to any one embodiment.

The timing controller T-C may receive an image signal RGB and a control signal CTRL. The timing controller T-C may generate an image data signal DAS obtained by converting a data format of the image signal RGB to match an interface specification of the data driver DDV. The timing controller T-C may output a gate control signal SCS, a data control signal DCS, and an emission control signal ECS in response to the control signal CTRL.

The voltage generator VG may generate voltages necessary for an operation of the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDV may receive the gate control signal SCS from the timing controller T-C. The scan driver SDV may output gate signals to the gate lines GIL1 to GILm, GWL1 to GWLm and GRL1 to GRLm in response to the gate control signal SCS. The gate signals may be applied to the pixels PX through the gate lines GIL1 to GILm, GWL1 to GWLm and GRL1 to GRLm.

The data driver DDV may receive the data control signal DCS and the image data signal DAS from the timing controller T-C. The data driver DDV may convert the image data signal DAS into data signals to output the data signals. The data signals may be defined as analog voltages corresponding to gray levels of the image data signal DAS. The data signals may be applied to the pixels PX through the data lines DL1 to DLn.

The emission driver EDV may receive the emission control signal ECS from the timing controller T-C. The emission driver EDV may output emission signals to the emission lines EML1 to EMLm in response to the emission control signal ECS. The emission signals may be applied to the pixels PX through the emission lines EML1 to EMLm.

The pixels PX may receive the data voltages in response to the gate signals. The pixels PX may display an image by emitting light with luminance corresponding to the data voltages in response to the emission signals.

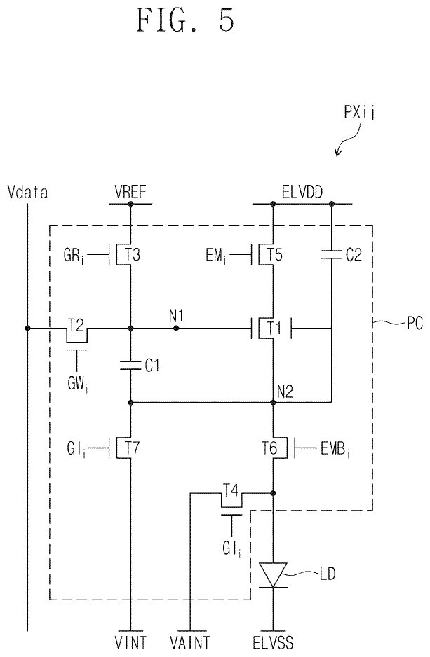

FIG. 5 is an equivalent circuit diagram of one of pixels according to an embodiment of the present disclosure. FIG. 5 illustrates a pixel PXij connected to i-th gate lines GWLi, GILi and GRLi, a j-th data line DLj, and an i-th emission line EMLi, wherein i and j are each a natural number. Hereinafter, the present disclosure will be described with reference to FIG. 5.

Referring to FIG. 5, the pixel PXij includes a light emitting element LD and a pixel driver PC. The light emitting element LD is connected to a first power line VDL and the pixel driver PC. The pixel driver PC may drive the light emitting element OLED. The pixel driver PC may include a plurality of transistors T1 to T7 and capacitors C1 and C2. The transistors T1 to T7 and the capacitors C1 and C2 may control an amount of current flowing through the light emitting element OLED. The light emitting element OLED may generate light having a certain luminance according to an amount of received current.

The pixel driver PC may be connected to i-th gate lines GWLi, GILi and GRLi, the i-th emission line EMLi, and the j-th data line DLj. In addition, the pixel PXij may be connected to the power lines connected to the voltage generator VG and receive a first initialization voltage VINT, a second initialization voltage VAINT, a reference voltage VREF, a first power voltage ELVDD, and a second power voltage ELVSS.

FIG. 5 illustrates signals transmitted to the pixel PXij. An i-th write gate line GWLi may receive an i-th write gate signal GWi. An i-th initialization gate line GILi may receive an i-th initialization gate signal GIi, and an i-th reset gate line GRLi may receive an i-th reset gate signal GRi. An i-th emission line EMLi may receive an i-th emission signal EMi, and an i-th bias emission line EBLi may receive an i-th bias emission signal EMBi. The j-th data line DLj receives a data voltage Vdata. A first initialization line VIL1 may receive the first initialization voltage VINT, and a second initialization line VIL2 may receive the second initialization voltage VAINT. A reference line VRL may receive the reference voltage VREF. The first power line PL1 may receive the first driving voltage ELVDD, and the second power line PL2 may receive the second driving voltage ELVSS.

The pixel driver PC may include first to seventh transistors T1, T2, T3, T4, T5, T6 and T7, a first capacitor C1, and a second capacitor C2. Each of the transistors T1 to T7 may include a source electrode, a drain electrode, and a gate electrode. Hereinafter, for convenience in FIG. 5, one of the source electrode and the drain electrode may be described as a first electrode, and the other may be described as a second electrode.

The transistors T1 to T7 may include the first to seventh transistors T1 to T7. In this embodiment, each of the first to seventh transistors T1 to T7 may be a transistor including an oxide semiconductor. Each of the first to seventh transistors T1 to T7 may be a p-type or an n-type.

The first transistor T1 may be connected between emission control transistors T5 and T6 to be described later. A gate of the first transistor T1 may be connected to a first node N1. A first electrode of the first transistor T1 may be connected to the fifth transistor T5, and a second electrode thereof may be connected to a second node N2. The second electrode of the first transistor T1 may be connected to the sixth transistor T6, the seventh transistor T7, the first capacitor C1, and the second capacitor C2 through the second node N2. The first transistor T1 may be a drive transistor. The first transistor T1 may control driving current flowing through the light emitting element LD corresponding to a voltage of the first node N1. Here, a first power voltage EL VDD may be set to a voltage having a higher potential level than the second power voltage ELVSS.

Meanwhile, the first transistor T1 may further include a bottom gate. That is, the first transistor T1 may have a dual-gate structure. The bottom gate may be connected to the second node N2, and the second node N2 may be connected to the second electrode of the first transistor T1. That is, the bottom gate of the first transistor T1 may form a source-sync structure. The first transistor T1 according to the present disclosure may have the source-sync structure, thereby providing a channel region in which a driving range is secured. Thus, due to the broadened driving range, the driving current may be precisely controlled even at a low gray level to have an effect of improving image quality at the low gray level. This will be described later in detail.

The second transistor T2 may be disposed between the first transistor T1 and the j-th data line DLj and be connected to the first transistor T1 and the j-th data line DLj. The second transistor T2 may include a gate connected to the write gate line GWLi, a first electrode connected to the data line DLj, and a second electrode connected to the first node N1. The second transistor T2 may supply a voltage Vdata to the first node N1 in response to the i-th write gate signal GWi transmitted through the write gate line GWLi. When the second transistor T2 receives the i-th write gate signal GWi, the second transistor T2 may be turned on and electrically connect the data line DLj to the first node N1.

The third transistor T3 may be connected between the first node N1 and a power line through which the reference voltage FREF is received. A first electrode of the third transistor T3 may receive the reference voltage VREF, and a second electrode of the third transistor T3 may be connected to the first node N1. In this embodiment, a gate of the third transistor T3 may receive the i-th reset gate signal GRi. When the reset gate signal GRi is supplied to the gate, the third transistor T3 may be turned on and provide the reference voltage VREF to the first node N1.

The fourth transistor T4 may be connected between the light emitting element LD and a power line through which the second initialization voltage VAINT is received. A first electrode of the fourth transistor T4 may be connected to an anode of the light emitting element LD and the sixth transistor T6, and a second electrode of the fourth transistor T4 may receive the first initialization voltage VAINT. The fourth transistor T4 may be referred to as a first initialization transistor. A gate of the fourth transistor T4 may receive the i-th initialization gate signal GIi. When the i-th initialization gate signal GIi is supplied to the gate, the fourth transistor T4 may be turned on and provide the second initialization voltage VAINT to the anode of the light emitting element LD.

The fifth transistor T5 may be connected between a power line, through which the first power voltage ELVDD is received, and the third node N3. A first electrode of the fifth transistor T5 receives the first power voltage ELVDD, and a second electrode of the fifth transistor T5 is connected to the first electrode of the first transistor T1. A gate of the fifth transistor T5 may receive the i-th emission signal EMi. The fifth transistor T5 may be referred to as a first emission control transistor. When the i-th emission signal EMi is supplied, the fifth transistor T5 is turned on and electrically connects the first electrode of the first transistor T1 to a power line through which the first power voltage ELVDD is received.

The sixth transistor T6 may be connected between the first transistor T1 and the light emitting element LD. Specifically, a first electrode of the sixth transistor T6 may be connected to the second node N2, and a second electrode thereof may be connected to the anode of the light emitting element LD. The first electrode of the sixth transistor T6 may be connected, through the second node N2, to the second electrode of the first transistor T1, the first capacitor C1, the seventh transistor T7, and the second capacitor C2. A gate of the sixth transistor T6 may receive the i-th bias emission line EBLi. The sixth transistor T6 may be referred to as a second emission control transistor. When the i-th bias emission line EBLi is supplied, the sixth transistor T6 may be turned on and electrically connect the light emitting element LD to the first transistor T1.

Meanwhile, in this embodiment, the fifth transistor T5 and the sixth transistor T6 are illustrated as being each independently turned on in response to the different emission signals EMi and EMBi. However, this is illustrated as an example, and the fifth transistor T5 and the sixth transistor T6 may be turned on in response to the same signal. Alternatively, one of the fifth transistor T5 and the sixth transistor T6 may be omitted in the pixel driver PC according to an embodiment of the present disclosure.

The seventh transistor T7 may be connected between the second node N2 and the power line through which the first initialization voltage VINT is received. A first electrode of the seventh transistor T7 may be connected, through the second node N2, to the first capacitor C1, the first transistor T1, the sixth transistor T6, and the second capacitor C2. A second electrode of the seventh transistor T7 may receive the first initialization voltage VINT. The seventh transistor T7 may be referred to as a second initialization transistor. A gate of the seventh transistor T7 may receive the i-th initialization gate signal GIi. When the i-th initialization gate signal GIi is supplied to the gate, the seventh transistor T7 be turned on and provide the first initialization voltage VINT to one electrode of the first capacitor C1 and the second electrode of the first transistor T1.

Meanwhile, in this embodiment, the fourth transistor T4 and the seventh transistor T7 are illustrated as being turned on in response to the same signal (GIi). However, this is illustrated as an example, and the fourth transistor T4 and the seventh transistor T7 may be each independently turned on in response to distinguished gate signals.

The first capacitor C1 may be disposed between the first node N1 and the second node N2. The first capacitor C1 may store a difference voltage between the first node N1 and the second node N2. The first capacitor C1 may be referred to as a storage capacitor.

The second capacitor C2 may be disposed between the second node N2 and a power line through which the first power voltage ELVDD is received. That is, one electrode of the second capacitor C2 may receive the first power voltage ELVDD, and the other electrode of the second capacitor C2 may be connected, through the second node N2, to the first transistor T1, the sixth transistor T6, the seventh transistor T7, and the first capacitor C1. The second capacitor C2 may store charges corresponding to a voltage difference between the first power voltage ELVDD and the second node N2. The second capacitor C2 may be referred to as a hold capacitor. The second capacitor C2 may have a higher storage capacity than the first capacitor C1. Accordingly, the second capacitor C2 may reduce (and/or minimize) a voltage change of the third node N3 in response to a voltage change of the first node N1.

Meanwhile, the number or connection relationships of the transistors and the number or connection relationships of the capacitors, which constitute the pixel driver PPC according to an embodiment of the present disclosure, may be variously changed and are not limited to any one embodiment.

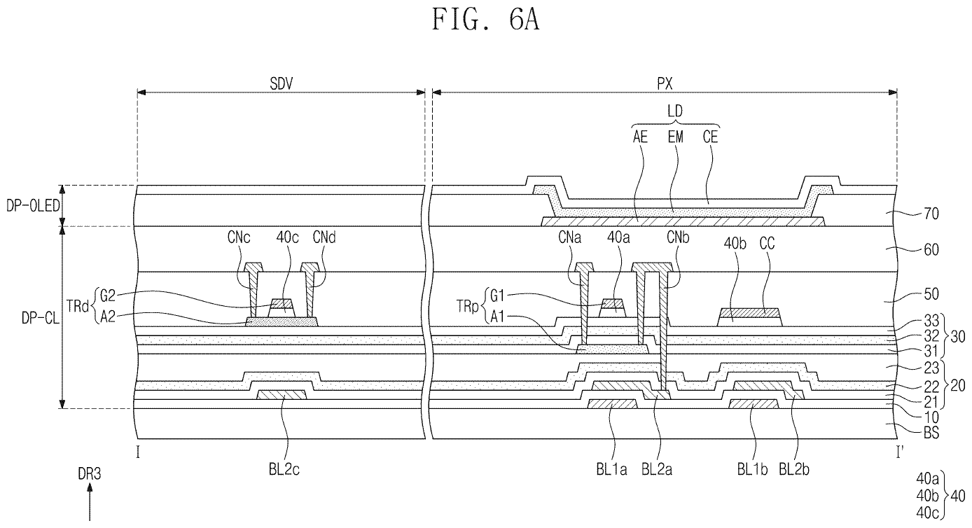

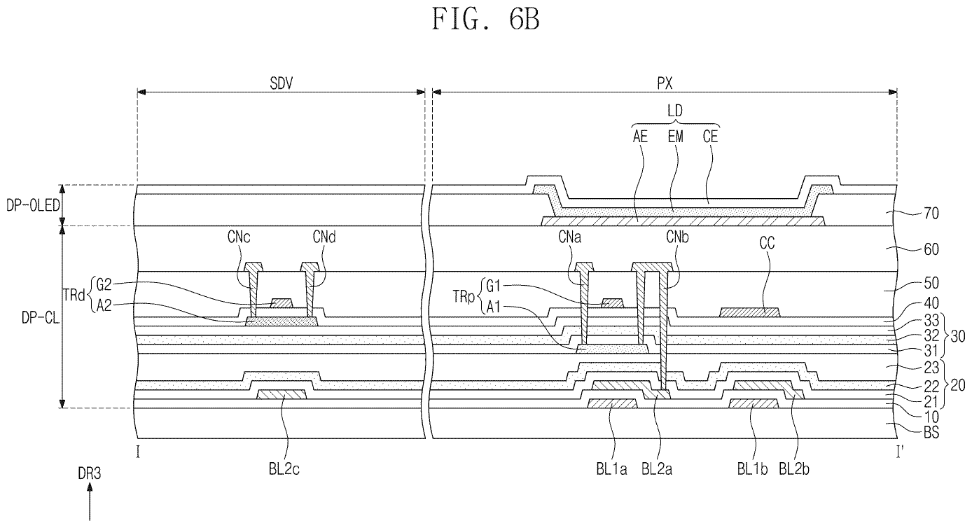

FIGS. 6A and 6B are cross-sectional views of a display panel according to an embodiment of the present disclosure. FIGS. 6A and 6B each illustrate a cross-section taken along line I-I′ illustrated in FIG. 4, and illustrate an embodiment in which a scan driver SDV is mounted on a display panel DP. FIGS. 6A and 6B illustrate cross-sectional views of different embodiments. Hereinafter, the present disclosure will be described with reference to FIGS. 6A and 6B.

FIG. 6A illustrates a substrate BS, a circuit element layer DP-CL, and a display element layer DP-OLED. The substrate BS may include a glass substrate, a sapphire substrate, a plastic film, or an organic/inorganic stack film. The substrate BS may have a multilayer structure or a single-layer structure. For example, the substrate BS may have a structure in which a plurality of plastic films coupled to each other through an adhesive are stacked, or a structure in which a glass substrate and a plastic film coupled to each other through an adhesive are stacked. The substrate BS may have flexibility. For example, the substrate BS may include polyimide (PI). However, this is illustrative, and the substrate BS may be provided in a rigid state and is not limited to any one embodiment.

The circuit element layer DD-CL is disposed on the substrate SUB. The circuit element layer DD-CL may include driving elements and a plurality of insulating layers 10, 20, 30, 40, 50 and 60. The driving elements may include one transistor TRp (hereinafter referred to as a pixel transistor) among the transistors constituting the pixel driver PC (see FIG. 5), one capacitor, and one transistor TRd (hereinafter referred to as a driver transistor) constituting the scan driver SDV (see FIG. 4). The insulating layers 10, 20, 30, 40, 50 and 60 may include first to sixth insulating layers 10, 20, 30, 40, 50 and 60 which are stacked, in sequence, on the substrate SB, but this is illustrated as an example. The number of the insulating layers constituting the circuit element layer DD-CL may be variously changed and is not limited to any one embodiment.

A first lower layer may be disposed on the substrate SB. The first lower layer may include a plurality of first lower patterns BL1a and BL1b. The first lower patterns BLla and BL1b may be disposed and constitute a pixel PX. The first lower patterns BL1a and BL1b may include a conductive material and include a metal. Alternatively. the first lower patterns BL1a and BL1b may include a light blocking material. The first lower patterns BL1a and BL1b may include the same material but are not limited thereto, and the first lower patterns BL1a and BL1b may include different materials and are not limited to any one embodiment.

The first insulating layer 10 is disposed on the substrate SB and covers the first lower patterns BL1a and BL1b.

A second lower layer may be disposed on the first insulating layer 10. The second lower layer may include a plurality of second lower patterns BL2a, BL2b and BL2c.

Among the second lower patterns BL2a, BL2b and BL2c illustrated in FIG. 6A, two second lower patterns BL2a and BL2b may be arranged to overlap the first lower patterns BL1a and BL1b, respectively. The two second lower patterns BL2a and BL2b may constitute the pixel PX. One (BL2a) of the two second lower patterns BL2a and BL2b may function as a bottom gate of the pixel transistor TRp and be connected to the pixel transistor TRp. The other (BL2b) of the two second lower patterns BL2a and BL2b may be one electrode of the capacitor C1.

The remaining one second lower pattern BL2c of the two second lower patterns BL2a, BL2b and BL2c illustrated in FIG. 6A may constitute the scan driver SDV. The second lower patterns BL2a, BL2b and BL2c may each include a conductive material and include a metal. The second lower patterns BL2a, BL2b and BL2c may include the same material but are not limited thereto, and the second lower patterns BL2a, BL2b and BL2c may include different materials and are not limited to any one embodiment.

The second insulating layer 20 is disposed on the first insulating layer 10 and covers the second lower patterns BL2a, BL2b and BL2c. The second insulating layer 20 may fully cover the substrate SB. The second insulating layer 20 may include a buffer layer. That is, the second insulating layer 20 may reduce surface energy of a surface on which the circuit element layer DP-CL is provided, so that the transistors TRp and TRd and the capacitor are stably provided on the substrate SUB.

Meanwhile, the second insulating layer 20 may include a first lower oxide layer 21, a first nitride layer 22, and a first upper oxide layer 23 which are stacked in sequence. That is, the second insulating layer 20 may include three insulating layers which are stacked in sequence.

The first lower oxide layer 21 may be a low-hydrogen layer having a low hydrogen content. The first lower oxide layer 21 may include a silicon oxide. That is, the first lower oxide layer 21 may include a material having a chemical formula SiOₓ. For example, the first lower oxide layer 21 may include a silicon oxide (SiO₂). However, example embodiments are not limited thereto.

The first nitride layer 22 may have a higher hydrogen content than the first lower oxide layer 21. The first nitride layer 22 may include a silicon nitride or a silicon oxynitride. That is, the first nitride layer 22 may have relatively high specific gravity of nitrogen compared to the first lower oxide layer 21 or the first upper oxide layer 23. The first nitride layer 22 may include a material having a chemical formula SiNₓ or SiON. However, example embodiments are not limited thereto.

The first upper oxide layer 23 may be a low-hydrogen layer having a low hydrogen content. The first upper oxide layer 23 may include a silicon oxide. That is, the first upper oxide layer 23 may include a material having a chemical formula SiOₓ. For example, the first upper oxide layer 23 may include a silicon oxide (SiO₂). In this embodiment, the first upper oxide layer 23 may include the same material as the first lower oxide layer 21. However, this is illustrative, and the first upper oxide layer 23 and the first lower oxide layer 21 may each independently include a material and thus may include different materials, and are not limited to any one embodiment.

The pixel transistor TRp may be disposed on the second insulating layer 20. A case in which the pixel transistor TRp is the first transistor T1 (see FIG. 5) illustrated in FIG. 5 is illustrated as an example. However, this is illustrated as an example, and the pixel transistor TRp may correspond, in common, to the second to seventh transistors T2 to T7 illustrated in FIG. 5, and is not limited to any one embodiment.

The pixel transistor TRp may include a gate G1 (hereinafter referred to as a first gate) and a semiconductor layer A1 (hereinafter referred to as a first semiconductor layer). The first semiconductor layer A1 may be disposed on the second insulating layer 20. The first semiconductor layer A1 may include an oxide semiconductor. For example, the first semiconductor layer A1 may include at least one of indium, gallium, or zinc. In this embodiment, the first semiconductor layer A1 may include an indium gallium zinc oxide (IGZO) or an indium gallium oxide (IGO). However, example embodiments are not limited thereto.

The first semiconductor layer A1 may be divided into a source region, a drain region, and a channel region according to conductivity. Specifically, the channel region may be a region having a relatively low conductivity compared to the source region and the drain region, and may overlap the first gate G1.

The source region and the drain region may be regions spaced apart from each other with the channel region therebetween, and may each be a region having conductor properties. Each of the source region and the drain region may be formed through doping or reduction. For example, in an oxide semiconductor pattern, a reduction region may have a higher conductivity than a non-reduction region. A metal oxide constituting the oxide semiconductor pattern may be precipitated into a metal through a reduction process, and thus a region in which the metal oxide is reduced may become each of the source region and the drain region, and a region in which the metal oxide remains may become the channel region.

The third insulating layer 30 is disposed on the second insulating layer 20 and covers the first semiconductor layer A1. The third insulating layer 30 is disposed between the first semiconductor layer A1 and the first gate G1. The third insulating layer 30 may be a gate insulating layer of the pixel transistor TRp. That is, the pixel transistor TRp may have a top-gate structure.

The third insulating layer 30 according to this embodiment may include a second lower oxide layer 31, a second nitride layer 32, and a second upper oxide layer 33 which are stacked in sequence. That is, the third insulating layer 30 may include three insulating layers which are stacked in sequence.

The second lower oxide layer 31 may be a low-hydrogen layer having a low hydrogen content. The second lower oxide layer 31 may include a silicon oxide. That is, the second lower oxide layer 31 may include a material having a chemical formula SiOₓ. For example, the second lower oxide layer 31 may include a silicon oxide (SiO₂).

The second nitride layer 32 may have a higher hydrogen content than the second lower oxide layer 31. The second nitride layer 32 may include a silicon nitride or a silicon oxynitride. That is, the second nitride layer 32 may have relatively high specific gravity of nitrogen compared to the second lower oxide layer 31 or the second upper oxide layer 33. The second nitride layer 32 may include a material having a chemical formula SiNₓ or SiON. However, example embodiments are not limited thereto.

A thickness of the second nitride layer 32 may be the same or less than a thickness of the first nitride layer 22. For example, the thickness of the second nitride layer 32 may be about 100 Å to about 2000 Å. The second nitride layer 32 may serve to provide hydrogen to the first semiconductor layer A1. Thus, when the thickness of the second nitride layer 32 is less than 100 Å, it may be difficult to provide sufficient hydrogen to the first semiconductor layer A1. In addition, when the thickness of the second nitride layer 32 is more than 100 Å, hydrogen may be excessively provided, and controlling the channel region by the first gate Al may be difficult.

The second upper oxide layer 33 may be a low-hydrogen layer having a low hydrogen content. The second upper oxide layer 33 may include a silicon oxide. That is, the second upper oxide layer 33 may include a material having a chemical formula SiOₓ. For example, the second upper oxide layer 33 may include a silicon oxide (SiO₂). In this embodiment, the second upper oxide layer 33 may include the same material as the second lower oxide layer 31. However, this is illustrative, and the second upper oxide layer 33 and the second lower oxide layer 31 may each independently include a material and thus may include different materials, and are not limited to any one embodiment.

A thickness of the second upper oxide layer 33 may be less than a thickness of the second nitride layer 32. The third insulating layer 30 according to the present disclosure may be disposed between the first semiconductor layer A1 and the first gate G1 to be described later, and function as the gate insulating layer of the pixel transistor TRp. In the third insulating layer 30, the thickness of the second nitride layer 32 may be sufficiently secured to sufficiently secure a separation distance between the first gate G1 and the first semiconductor layer A1. Thus, the thickness of the second upper oxide layer 33 may be variously designed, and may be provided to be less than the thickness of the second nitride layer 32, thereby reducing an influence on a component provided on the second nitride layer 32. For example, the thickness of the second upper oxide layer 33 may be 200 Å or less, but example embodiments are not limited thereto. As long as being less than the thickness of the second nitride layer 32, the thickness of the second upper oxide layer 33 may be provided as various embodiments and is not limited to any one embodiment.

The display panel DP according to the present disclosure may include the second nitride layer 32 to supply necessary hydrogen to the first semiconductor layer A1. As described above, the first semiconductor layer A1 may include an indium gallium zinc oxide, and this may be a material required by a gate insulating layer having a high hydrogen concentration. The second nitride layer 32 may have a high hydrogen concentration, and thus stably provide supply hydrogen required by the first semiconductor layer A1. Thus, a driving range of the first semiconductor layer A1 may be secured, and/or reliability may be improved.

The driver transistor TRd may be disposed on the third insulating layer 30. The driver transistor TRd may include a gate G2 (hereinafter referred to as a second gate) and a semiconductor layer A2 (hereinafter referred to as a second semiconductor layer). The second semiconductor layer A2 may be disposed on the third insulating layer 30. That is, the driver transistor TRd may have a top-gate structure.

The second semiconductor layer A2 may include an oxide semiconductor. For example, the second semiconductor layer A2 may include at least one of indium, gallium, or zinc. The second semiconductor layer A2 may include a different material from the first semiconductor layer A1, and may include a material having a higher mobility than the first semiconductor layer A1. In this embodiment, the second semiconductor layer A2 may include an indium tin gallium zinc oxide (ITGZO). However, example embodiments are not limited thereto.

Like the first semiconductor layer A1, the second semiconductor layer A2 may be divided into a source region, a drain region, and a channel region according to conductivity. Specifically, the channel region may be a region having a relatively low conductivity compared to the source region and the drain region, and may overlap the second gate G2. The source region and the drain region may be regions spaced apart from each other with the channel region therebetween, and may each be a region having conductor properties. The source region and the drain region may be regions in which a metal oxide is reduced to include metal precipitate.

The second semiconductor layer A2 may be in contact with the second upper oxide layer 33 of the third insulating layer 30. The third insulating layer 30 may include the second nitride layer 32 to provide sufficient hydrogen to the first semiconductor layer A1. That is, a thickness for providing hydrogen to the first semiconductor layer A1 may be secured through the second nitride layer 32, and thus even when the thickness of the second upper oxide layer 33 is decreased, an influence on hydrogen supplied to the second semiconductor layer A2 may be reduced.

In the third insulating layer 30, the thickness of the second upper oxide layer 33 in contact with the second semiconductor layer A2 may be decreased, and thus a phenomenon in which a threshold voltage (Vth) of the second semiconductor layer A2 shifts in a negative direction may be reduced and/or prevented due to the second upper oxide layer 33. According to the present disclosure, the third insulating layer 30 may include the second upper oxide layer 33 having a small thickness, thereby shifting the threshold voltage of the second semiconductor layer A2 in a positive direction and/or improving reliability of the driver transistor TRd.

A plurality of insulating patterns 40a, 40b and 40c may be disposed on the second semiconductor layer A2. A plurality of gate electrode patterns G1, G2 and CC may be disposed on the insulating patterns 40a, 40b and 40c, respectively. The gate electrode patterns G1, G2 and CC may include the first gate G1, the second gate G2, and a capacitor electrode CC. The insulating patterns 40a, 40b and 40c may be patterned using the gate electrode patterns G1, G2 and CC as masks.

In the insulating patterns 40a, 40b and 40c, two insulating patterns 40a and 40b among the insulating patterns 40a, 40b and 40c may be disposed in the pixel PX. One (40a) of the two insulating patterns 40a and 40b may be disposed between the first semiconductor layer Al and the first gate G1 and function as a gate insulating layer of the pixel transistor TRp. The other (40b) of the two insulating patterns 40a and 40b may be disposed between the second lower pattern BL2b and the capacitor electrode CC and function as a dielectric layer of the first capacitor G1. The remaining one (40c) of the insulating patterns 40a, 40b and 40c may be disposed in the scan driver SDV and disposed between the second semiconductor layer A2 and the second gate G2, and function as a gate insulating layer of the driver transistor TRd.

The fifth insulating layer 50 may be disposed on the third insulating layer 30) and cover the insulating patterns 40a, 40b and 40c and the gate electrode patterns G1, G2 and CC. The fifth insulating layer 50 may include an organic layer or include an organic layer and an inorganic layer.

Electrode patterns CNa, CNb, CNc and CNd may be disposed on the fifth insulating layer 50. The electrode patterns CNa and CNb, which constitute the pixel PX, of the electrode patterns CNa, CNb, CNc and CNd may pass through the fifth insulating layer 50 and be respectively connected to the source region and the drain region of the first semiconductor layer A1. The electrode patterns CNc and CNd, which constitute the scan driver SDV, of the electrode patterns CNa, CNb, CNc and CNd may pass through the fifth insulating layer 50 and be respectively connected to the source region and the drain region of the second semiconductor layer A2.

Meanwhile, one (Cnb) of the electrode patterns CNa and CNb which constitute the pixel PX may be connected to the second lower pattern BL2a. Here, the second lower pattern BL2a may serve as a bottom gate with respect to the first semiconductor layer A1, and the pixel transistor TRp may have a dual-gate structure including a top gate (G1) and a bottom gate (BL2a). The pixel transistor TRp may have a source-sync structure, and here, the pixel transistor TRp illustrated in FIG. 6A may correspond to the first transistor T1 illustrated in FIG. 5. However, this is illustrated as an example, and the electrode patterns CNa, CNb, CNc and CNd may not connected to the second lower patterns BL2a and B12b, and are not limited to any one embodiment.

The sixth insulating layer 60 may be disposed on the fifth insulating layer 50 and cover the electrode patterns CNa, CNb, CNc and CNd. The display element layer DP-OLED may be disposed on the sixth insulating layer 60.

The display element layer DP-OLED may include a light emitting element LD and a seventh insulating layer 70. The seventh insulating layer 70 may be disposed on the sixth insulating layer 60 and provide a certain opening portion to the pixel PX. The seventh insulating layer 70 may function as a pixel defining film.

The light emitting element LD may include an anode AE, an emission layer EM, and a cathode CE. The seventh insulating layer 70 exposes at least a portion of the anode AE through the opening portion. The emission layer EM may be disposed in the opening portion and disposed between the anode AE and the cathode CE. The cathode CE may be disposed on the seventh insulating layer 70 and cover an entire display area. In this embodiment, the cathode CE is illustrated as extending up to the scan driver SDV, but example embodiments are not limited thereto. The cathode CE may not overlap the scan driver SDV and is not limited to any one embodiment.

Meanwhile, referring to FIG. 6B, in the display panel DP according to an embodiment of the present disclosure, a fourth insulating layer 40 may be provided as a layer having a shape of one body. The fourth insulating layer 40 is disposed on a third insulating layer 30 and fully covers a top surface of a second upper oxide layer 33.

Here, each of a first semiconductor layer A1 and a second semiconductor layer A2 may be divided into a channel region, a source region, and a drain region through a doping process. That is, in each of the first semiconductor layer A1 and the second semiconductor layer A2, regions having high dopant concentrations through the doping process may become the source region/the drain region, and the remaining region overlapping gates G1 and G2 may become the channel region. Meanwhile, a light doped region, which has a dopant concentration higher than that of the channel region but lower than that of the source region or the drain region, may be further provided between the source region or the drain region and the channel region, and is not limited to any one embodiment.

Even when the fourth insulating layer 40 is provided as insulating patterns 40a, 40b and 40c as illustrated in FIG. 6A or provided in one body as illustrated in FIG. 6B, the third insulating layer 30 may not be affected by the fourth insulating layer 40. Thus, the display panel according to an embodiment of the present disclosure may include the third insulating layer 30 including a second lower oxide layer 31, a second nitride layer 32, and a second upper oxide layer 33, thereby supplying sufficient hydrogen to the first semiconductor layer A1 and shifting a threshold voltage of the second semiconductor layer A2 in the positive direction. Thus, all characteristics required for the first semiconductor layer A1 and the second semiconductor layer A2, which have different materials, may be satisfied even through one insulating layer (30), thereby simplifying the process and the design.

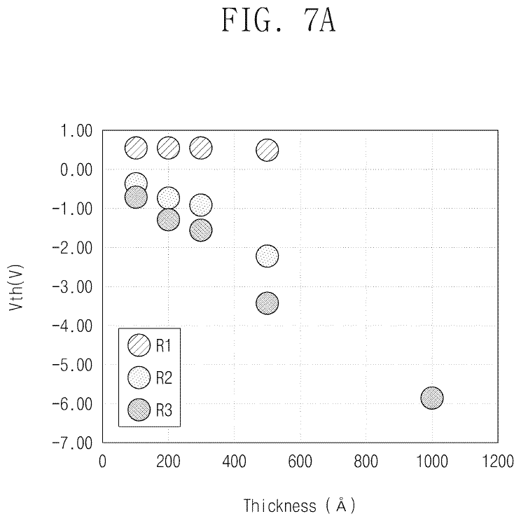

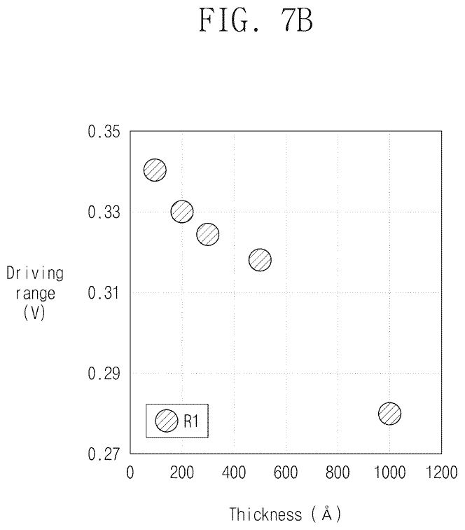

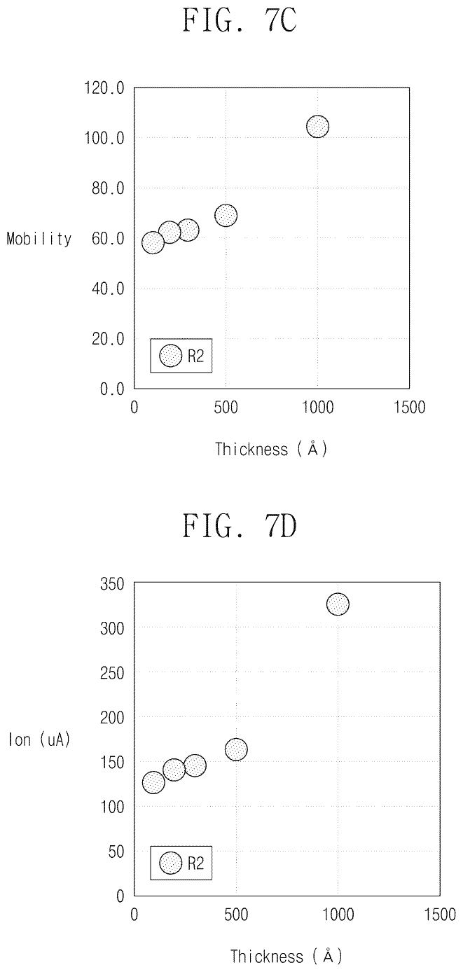

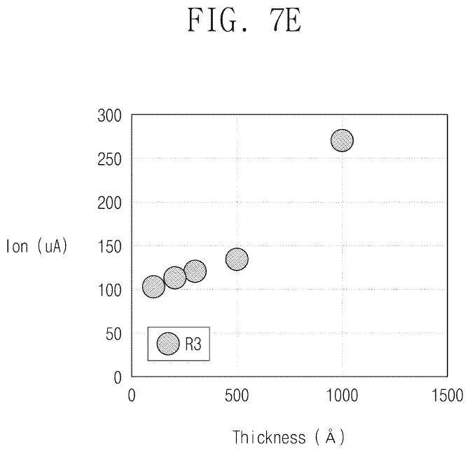

FIGS. 7A to 7E are each a graph illustrating changes in characteristics of a semiconductor layer according to a thickness of an insulating layer according to an embodiment of the present disclosure. In FIGS. 7A to 7E, an X axis indicates changes in thickness of the second upper oxide layer 33 (see FIG. 6A), and a Y axis indicates changes in characteristics such as threshold voltage (Vth), driving range, mobility, and on current (Iₒₙ) of a semiconductor layer. Specifically, FIG. 7A illustrates changes in threshold voltage (Vth) according to the thickness of the second upper oxide layer 33, and illustrates the changes for each of three embodiments R1, R2 and R3. FIG. 7B illustrates changes in driving range of a first embodiment R1 according to the thickness of the second upper oxide layer 33, and FIG. 7C illustrates changes in mobility of a second embodiment R2 according to the thickness of the second upper oxide layer 33. FIG. 7D illustrates changes in on current of the second embodiment R2 according to the thickness of the second upper oxide layer 33, and FIG. 7E illustrates changes in on current of a third embodiment R3 according to the thickness of the second upper oxide layer 33. Hereinafter, the present disclosure will be described with reference to FIGS. 7A to 7D.

The first embodiment R1 of the three embodiments R1, R2 and R3 may correspond to a case in which the first semiconductor layer A1 of the pixel transistor TRp (see FIG. 6A) has a bottom gate and a source-sync structure. The second embodiment R2 of the three embodiments R1, R2 and R3 may correspond to a case in which the second semiconductor layer A2 of the driver transistor TRd (see FIG. 6A) has a bottom gate and a source-sync structure. The third embodiment R3 of the three embodiments R1, R2 and R3 may correspond to a case in which the first semiconductor layer A1 of the pixel transistor TRp (see FIG. 6A) has a structure in which a bottom gate is omitted.

Referring to FIG. 7A, it may be known that as the thickness of the second upper oxide layer 33 adjacent to the semiconductor layer increases, the threshold voltage of the semiconductor layer tends to shift in the negative direction. Among the three embodiments R1, R2 and R3, the third embodiment R3 shows a sharpest shift, and the second embodiment R2 shows a relatively small shift and a deviation which is not large. However, a graph for the first embodiment R1 of the three embodiments R1, R2 and R3 shows that a shift in the negative direction does not relatively occur.

In addition, referring to FIG. 7B, it may be known that in the first embodiment R1, as the thickness of the second upper oxide layer 33 decreases, the driving range of the semiconductor layer A1 increases. In particular, in the first embodiment R1, the driving range of 0.31 or more may be secured even in a thickness range of 600 Å or less which has a reference positive value and in which a change in threshold voltage (Vth) is small.

That is, referring to FIGS. 7A and 7B, when like the first embodiment R1, the pixel transistor TRp has a source-synchronized structure through a bottom gate, a shift of the threshold voltage (Vth) in the negative direction according to the changes in thickness of the insulating layer may be small, and thus the driving range may be secured and stable driving may be enabled.

Referring to FIG. 7A again, it may be known that even in the second embodiment R2 and the third embodiment R3, a deviation in shift of the threshold voltage (Vth) is larger between the thicknesses before and after 400 Å. It may be known that when the thickness of the second upper oxide layer 33 is 400 Å, a degree of the shift of the threshold voltage (Vth) of the first semiconductor layer A1 in the negative direction may be relatively low, and the range of 400 Å shows the shift of −1 or less.

Referring to FIGS. 7C and 7D, it may be known that as the thickness of the second upper oxide layer 33 increases, the mobility and the on current (Iₒₙ) are increased in in the second embodiment R2. Here, it is shown that a deviation in mobility or on current (Iₒₙ) is large between the thicknesses of the second upper oxide layer 33 before and after 500 Å.

That is, referring to FIGS. 7A, 7C, and 7D, in the driver transistor TRd including the second semiconductor layer A2 disposed on the second upper oxide layer 33 like the second embodiment R2, when the thickness of the second upper oxide layer 33 is set to 200 Å or less, the excessive shift of the threshold voltage (Vth) of the second semiconductor layer A2 in the negative direction may not occur, and thus the driver transistor TRd may be easily controlled and/or the reliability may be improved. Here, the driver transistor TRd may be properly controlled such that the mobility or the on current (Ion) of the driver transistor TRd is not excessively increased, and also have sufficient mobility, thereby stably designing the scan driver SDV for driving the display panel with improved current characteristics and/or high resolution. According to the present disclosure, the driver transistor TRd may be provided as a semiconductor layer having high mobility, thereby reducing a surface area of the scan driver SDV and providing an electronic apparatus with applied high-resolution circuit design and also a reduced bezel area.

In addition, referring to FIGS. 7A and 7E, it may be known that as the thickness of the second upper oxide layer 33 increases, the on current is increased even in the third embodiment R3 like the second embodiment R2, and it may be known that the third embodiment R3 shows a relatively lower value of the on current (Iₒₙ) than the second embodiment R2, but a deviation not large, and an increase pattern similar to FIG. 7D.

According to the present disclosure, as the second nitride layer 32 is included, even when the first semiconductor layer A1 of the driver transistor TRd has the relatively low mobility, hydrogen may be sufficiently supplied to provide the electronic apparatus having the pixel driver PC with secured driving range and/or improved reliability.

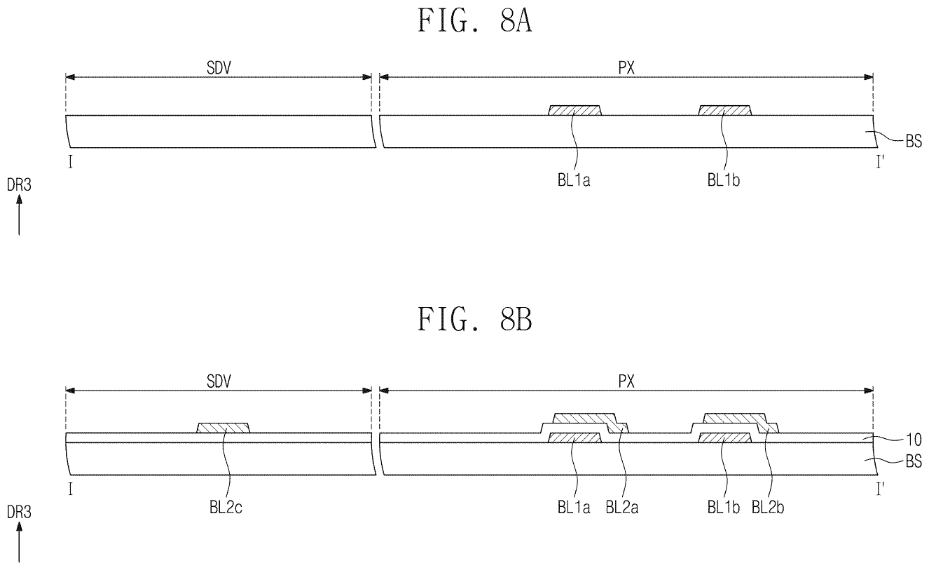

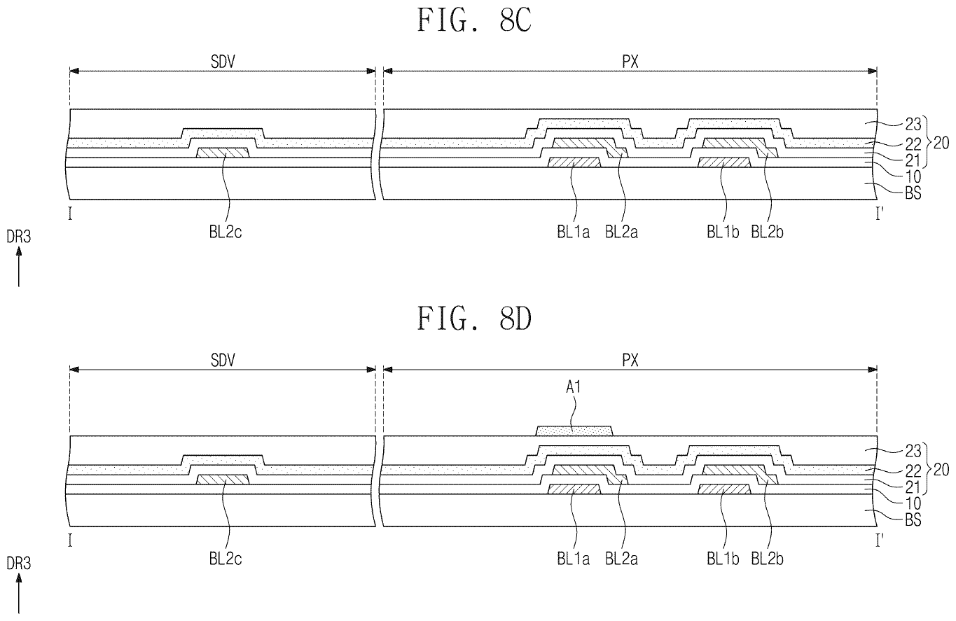

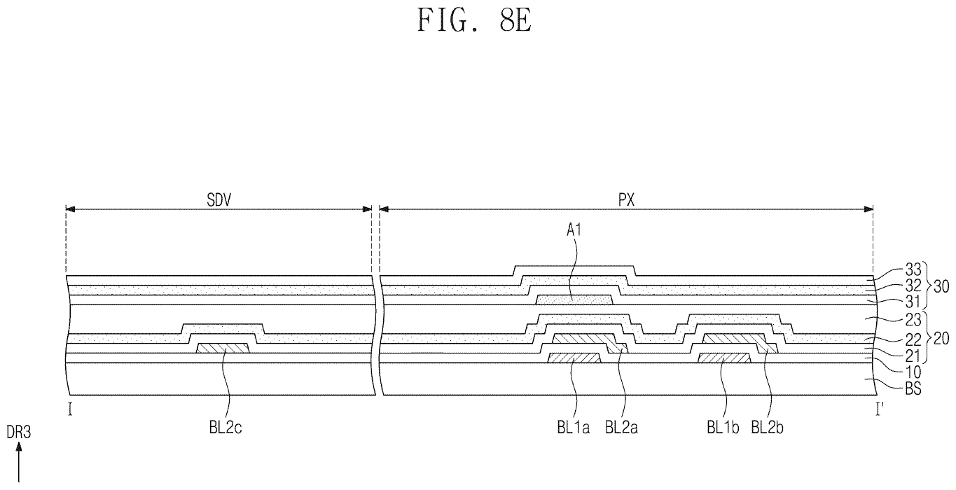

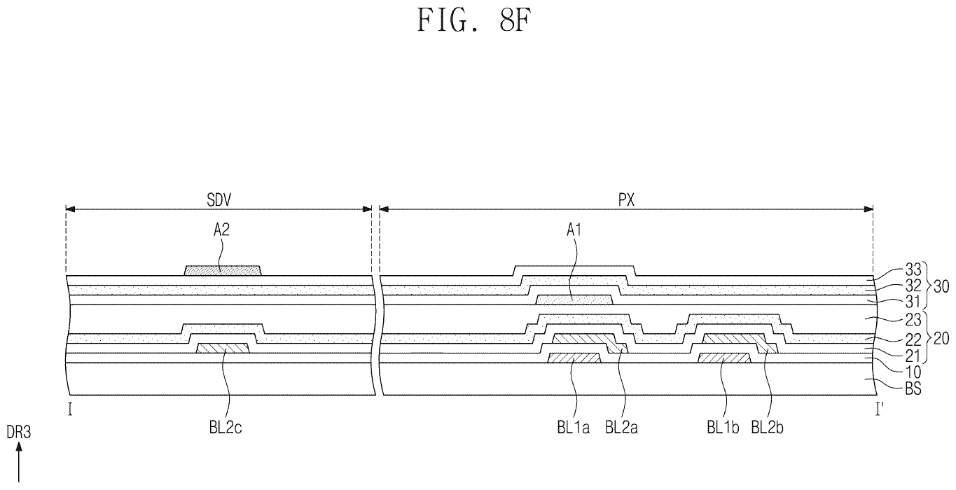

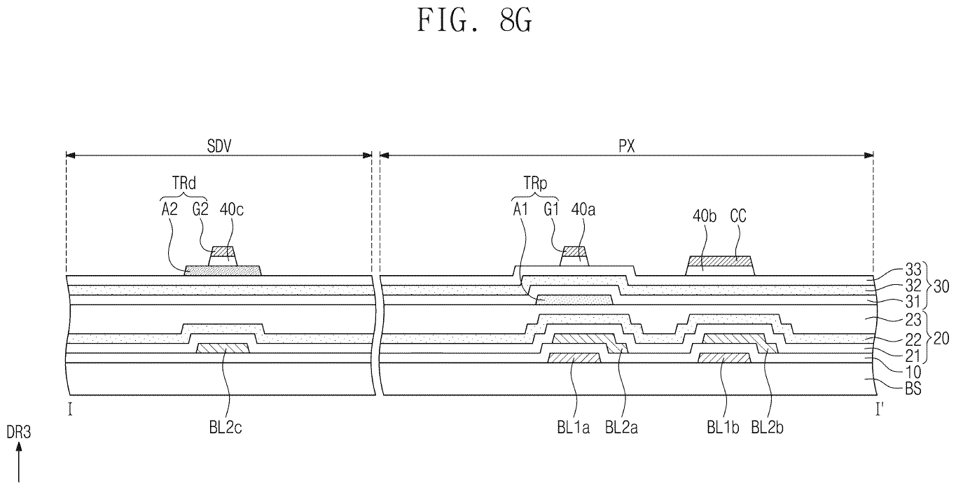

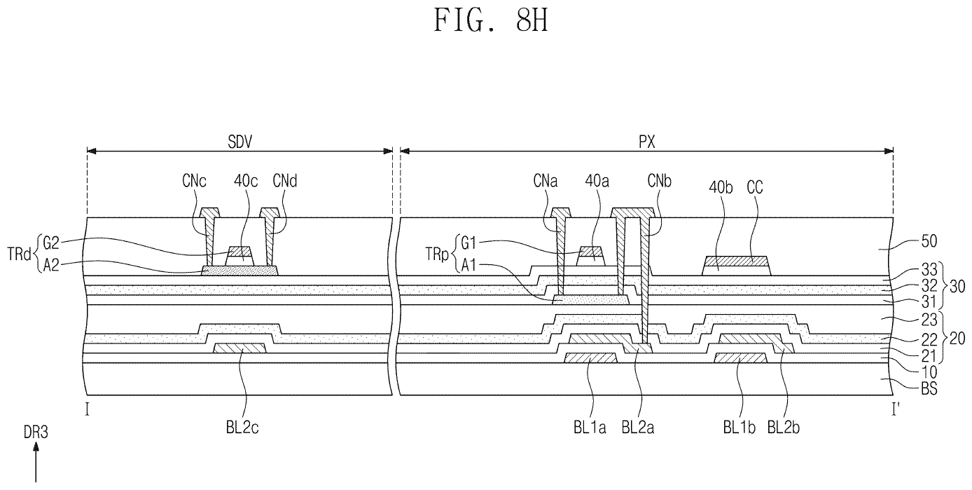

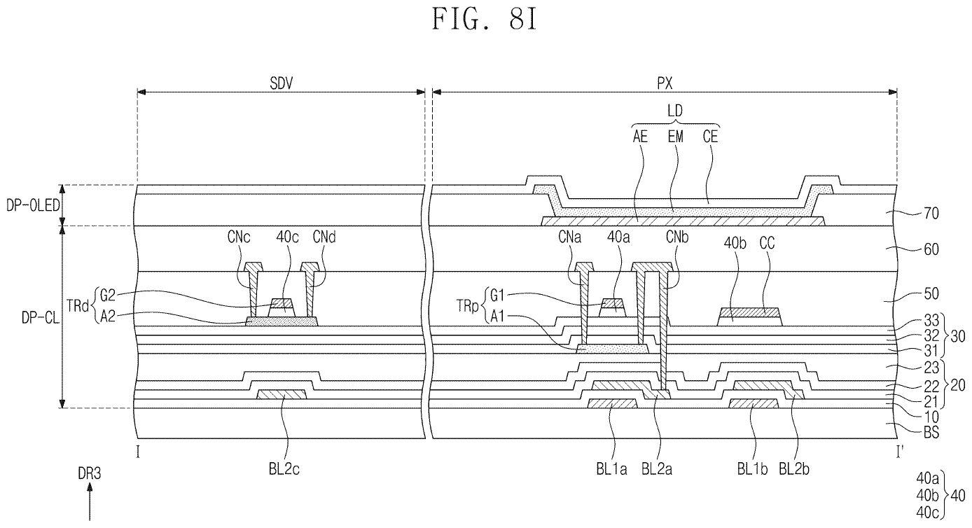

FIGS. 8A to 8I are cross-sectional views illustrating a method for manufacturing a display panel according to an embodiment of the present disclosure. As an example, FIGS. 8A to 8I illustrate a manufacturing method for an embodiment illustrated in FIG. 6A. Hereinafter, the present disclosure will be described with reference to FIGS. FIGS. 8A to 8I. Meanwhile, components like the components described with reference to FIGS. 1 to 7 will be designated by like reference symbols, and redundant contents will be omitted.

Referring to FIG. 8A, a first lower layer may be formed on a base substrate (or substrate) BS. The first lower layer may include a plurality of first lower patterns BL1a and BL1b. A conductive layer may be formed on the substrate BS through deposition or coating, and then patterned to form the first lower patterns BL1a and BL1b.

Thereafter, referring to FIG. 8B, a first insulating layer 10 and a second lower layer may be formed in sequence. After the forming of the first lower patterns BL1a and BL1b, an insulating material may be deposited or applied onto the substrate BS to form the first insulating layer 10. The insulating material may be an inorganic insulating material. A conductive layer may be deposited or applied onto the first insulating layer 10 and then patterned to form a plurality of second lower patterns BL2a, BL2b and BL2c.

Thereafter, referring to FIG. 8C, a second insulating layer 20 may be formed. A first lower oxide layer 21, a first nitride layer 22, and a first upper oxide layer 23 may be stacked in sequence to form the second insulating layer 20. Each of the first lower oxide layer 21, the first nitride layer 22, and the first upper oxide layer 23 may be formed on an entire surface of the substrate BS. The first lower oxide layer 21 and the first upper oxide layer 23 may each include a material including a silicon oxide. The first lower oxide layer 21 and the first upper oxide layer 23 may include the same material or different materials. The first nitride layer 22 may include a material including a silicon nitride or a silicon oxynitride. However, example embodiments are not limited thereto.

The first lower oxide layer 21, the first nitride layer 22, and the first upper oxide layer 23 may be deposited or applied in sequence to form the second insulating layer 20. For example, each of the first lower oxide layer 21, the first nitride layer 22, and the first upper oxide layer 23 may be formed through a chemical vapor deposition process. The first lower oxide layer 21, the first nitride layer 22, and the first upper oxide layer 23 may be deposited in sequence with different deposition sources in the same chamber or may be each independently formed in different chambers, and are not limited to any one embodiment.

Thereafter, referring to FIG. 8D, a first semiconductor layer A1 may be formed on the second insulating layer 20. A first semiconductor material may be deposited or applied onto the second insulating layer 20 and then patterned to form the first semiconductor layer A1. The first semiconductor material may include an oxide semiconductor. For example, the first semiconductor material may include an indium gallium zinc oxide (IGZO) or an indium gallium oxide (IGO). However, example embodiments are not limited thereto.

Thereafter, referring to FIG. 8E, a third insulating layer 30 may be formed. The third insulating layer 30 is formed on the second insulating layer 20 and covers the first semiconductor layer A1. A second lower oxide layer 31, a second nitride layer 32, and a second upper oxide layer 33 may be stacked in sequence to form the third insulating layer 30.

Each of the second lower oxide layer 31, the second nitride layer 32, and the second upper oxide layer 33 may be formed on the entire surface of the substrate BS. An insulating material may be deposited or applied to form each of the second lower oxide layer 31, the second nitride layer 32, and the second upper oxide layer 33. The second lower oxide layer 31 and the second upper oxide layer 33 may each include a material including a silicon oxide (SiOₓ). However, this is illustrative, and as long as being a low-hydrogen oxide layer, for example, an oxide layer having a hydrogen concentration of about 3*10¹⁹ mol/cm³, the oxide layer is not limited to any one embodiment.

The second nitride layer 32 may include a material including a silicon nitride (SiOₓ) or a silicon oxynitride (SiON). However, this is illustrative, and as long as having a higher hydrogen concentration than each of the second lower oxide layer 31 and the second upper oxide layer 33, the second nitride layer 32 may include various materials and is not limited to any one embodiment.

The second lower oxide layer 31, the second nitride layer 32, and the second upper oxide layer 33 may be deposited or applied in sequence to form the third insulating layer 30. For example, each of the second lower oxide layer 31, the second nitride layer 32, and the second upper oxide layer 33 may be formed through the chemical vapor deposition process. The second lower oxide layer 31, the second nitride layer 32, and the second upper oxide layer 33 may be deposited in sequence with different deposition sources in the same chamber or may be each independently formed in different chambers, and are not limited to any one embodiment.

The second nitride layer 32 may supply hydrogen to the first semiconductor layer A1. Hydrogen included in the second nitride layer 32 may be provided to the first semiconductor layer A1 to improve mobility of the first semiconductor layer A1. Thus, a driving range of the first semiconductor layer A1 may be broadened, and constant current stress (CCS) characteristics may be improved to form the first semiconductor layer A1 with improved reliability.

The second nitride layer 32 may be formed to have a thickness which is not larger than a thickness of the first nitride layer 22. For example, when the first nitride layer 22 has a thickness of about 2000 Å, the second nitride layer 32 may have a thickness of about 100 Å to about 2000 Å. According to the present disclosure, the thickness of the second nitride layer 32 may be designed to be in an optimum range, thereby easily controlling hydrogen provided to the first semiconductor layer A1 and allowing a first gate G1 to easily controlling a channel region of the first semiconductor layer A1.

The second upper oxide layer 33 may be formed to have a smaller thickness than the second nitride layer 32. For example, the second upper oxide layer 33 may have a thickness of 200 Å or less.

Thereafter, referring to FIG. 8F, a second semiconductor layer A2 may be formed on the third insulating layer 30. A second semiconductor material may be deposited or applied onto the third insulating layer 30 and then patterned to form the second semiconductor layer A2. The second semiconductor layer A2 may be formed in an area in which a scan driver SDV is disposed. The second semiconductor material may be an oxide semiconductor material which is different from the first semiconductor material and has a higher mobility than the first semiconductor material. For example, when the first semiconductor material is an indium gallium zinc oxide (IGZO), the second semiconductor material may include an indium tin gallium zinc oxide (ITGZO). However, example embodiments are not limited thereto.

According to the present disclosure, the second upper oxide layer 33 may be formed to be thin, thereby limiting and/or preventing a phenomenon in which a threshold voltage of the second semiconductor layer A2 is shifted in the negative direction by the second upper oxide layer 33. According to the present disclosure, the threshold voltage of the second semiconductor layer A2 may be formed to have a value of more than 0, and on current (Ion) may be easily secured.

Thereafter, referring to FIG. 8G, a plurality of insulating patterns 40a, 40b and 40c and a plurality of gate patterns G1, G2 and CC may be formed. An insulating material layer is formed by depositing or applying an insulating material onto the third insulating layer 30 so that the second semiconductor layer A2 is covered. Thereafter, a conductive material may be deposited or applied to form a conductive layer. Then, the conductive layer may be patterned to form the first gate G1, a second gate G2, and a capacitor electrode CC, and the insulating material layer may be etched using the first gate G1, the second gate G2, and the capacitor electrode CC as masks, thereby forming the insulating patterns 40a, 40b and 40c.

Meanwhile, regions, which are covered by the insulating patterns 40a, 40b and 40c, of the second semiconductor layer A2 may be reduced and formed as a source region and a drain region, respectively. Accordingly, the source region and the drain region of the second semiconductor layer A2 may be self-aligned with the second gate G2.

Thereafter, referring to FIG. 8H, a fifth insulating layer 50 may be formed and a plurality of connection electrodes CNa, CNb, CNc and CNd may be formed. An insulating material may be deposited or applied to form the fifth insulating layer 50. Then, through-holes may be formed in the fifth insulating layer 50 or the third insulating layer 30 and the fifth insulating layer 50. A conductive layer may be formed and then patterned to form the connection electrodes CNa, CNb, CNc and CNd. The connection electrodes CNa, CNb, CNc and CNd may be respectively filled in corresponding ones of the through-holes and be connected to the source region and the drain region of the first semiconductor layer A1, and the source region and the drain region of the second semiconductor layer A2.

Thereafter, referring to FIG. 8I, a seventh insulating layer 70 and a light emitting element LD may be formed to form a display element layer DP-OLED. A conductive material may be deposited to form a conductive layer, and then the conductive layer may be patterned to form an anode AE. Thereafter, an insulating material may be deposited or applied to form an insulating material layer, and then an opening portion may be formed to form the seventh insulating layer 70. Then, an emission layer EM and a cathode CE may be formed in sequence to form the display element layer DP-OLED.

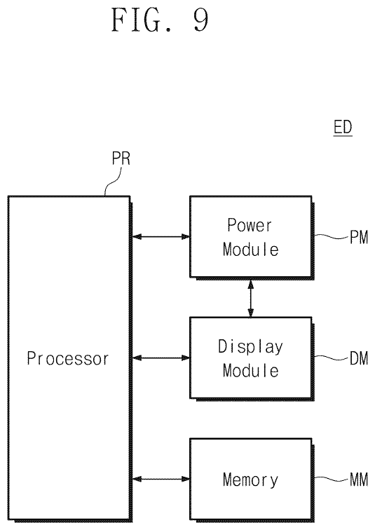

FIG. 9 is a block diagram of an electronic apparatus according to an embodiment. Referring to FIG. 9, an electronic apparatus ED according to an embodiment may include a display module 11, a processor 12, a memory 13, and a power module 14. The electronic apparatus ED may correspond to the electronic apparatus DD illustrated in FIG. 1.

The processor 12 may include at least one of a central processing unit (CPU), an application processor (AP), a graphic processing unit (GPU), a communication processor (CP), an image signal processor (ISP), or a controller. In an embodiment, the processor 12 may be provided as divided into two or more in a functional or structural aspect. For example, the processor 12 may include a main processor in the form of a first driving chip including the central processing unit, and a coprocessor in the form of a second driving chip including a controller which receives an image signal from the main processor and processes the image signal so as to be suitable for the specification of an interface with the display module 11.

The memory 15 may include at least one of a nonvolatile memory or a volatile memory. The memory 15 may store data information necessary for an operation of the processor 12 or the display module 11. When the processor 12 executes an application stored in the memory 15, an image data signal and/or an input control signal may be transmitted to the display module 11, and the display module 11 may process the received signal and output image information through a display screen.

The power module 14 may include a power supply module such as a power adapter or a battery device, and a power conversion module which converts the power supplied by the power supply module and generates power necessary for an operation of the electronic apparatus ED. The power conversion by the power conversion module may include DC-DC conversion, AC-DC conversion, and DC-AC conversion, and is not limited thereto.

At least one of the components of the electronic apparatus ED described above may be included in the display device according to embodiments described above. In addition, some of individual modules included as functional in one module may be included in the display device, and others may be provided separately from the display device. For example, the display device may include the display module 11, and the coprocessor of the processor 12, and the main processor of the processor 12, the memory 13, and the power module 14 may be provided not in the display device but in another type of device in the electronic apparatus ED. As another example, the power module 14 may be provided in the display device and supply power to the processor 12 and the memory 13 provided in the electronic apparatus ED, not in the display device, and is not limited to the foregoing example.

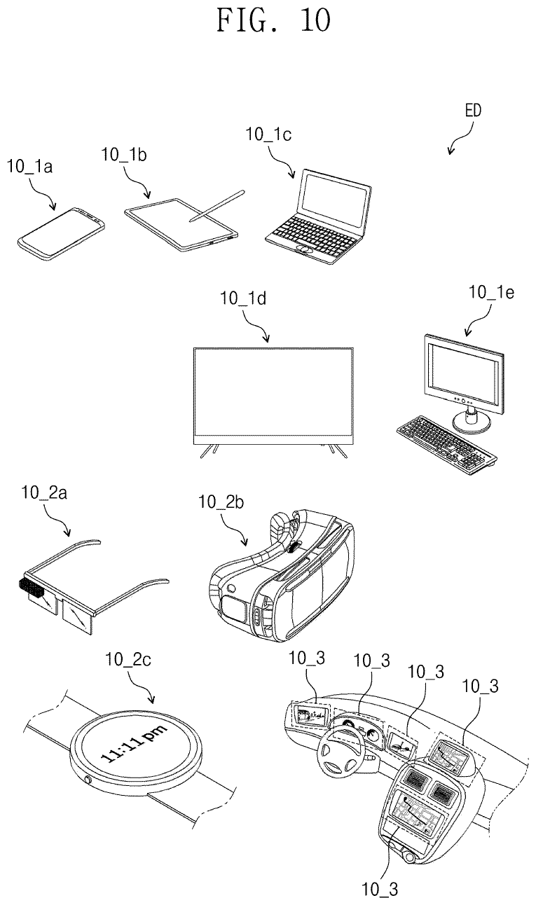

FIG. 10 is a schematic view of electronic apparatuses according to various embodiments.

Referring to FIG. 10, various electronic apparatuses to which a display device according to embodiments is applied may include not only an electronic apparatus for image display, e.g., a smartphone 10_1a, a tablet PC 10_1b, a laptop computer 10_1c, TV 10_1d, and a monitor for a desk computer 10_1e, but also a wearable electronic apparatus including a display module, e.g., smart glasses 10_2a, a head mounted display 10_2b, and a smartwatch 10_2c, and a vehicle electronic apparatus ED-3 including a display module, e.g., a vehicle instrument panel, a center fascia, a center information display (CID) disposed on a dashboard, and a room mirror display.

The electronic apparatus in FIG. 10 may include the components illustrated in FIG. 9. For example, the smartphone 10_1a may include the display module 11, the processor 12, the memory 13, and the power module 14 which are illustrated in FIG. 9. The smartphone 10_1a may further include a communication module and a battery device. Power provided by the battery device may be converted through the power module 14 and provided to the processor 12, the memory 13, and the display module 11. In an embodiment, a display device applied to the smartphone 10_1a may include the display module 11 and further include the power module 14. The processor 12 and the memory 13 may be provided in the form of a chip mounted on a mother board that is an external device, but are not limited thereto.

According to the present disclosure, the integration level of the scan driver may be improved to provide the electronic apparatus having the narrow bezel.

Moreover, according to the present disclosure, the driving range and the lifespan of the pixel transistor may be improved to provide the electronic apparatus with improved reliability.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims to be described later. Therefore, the technical scope of the present disclosure is not to be limited to the contents stated in the detailed description of the specification, but should be determined by the claims.

1. An electronic apparatus comprising:
a substrate;
a circuit element layer on the substrate, the circuit element layer comprising a scan driver and a pixel driver; and
a display element layer on the circuit element layer, the display element layer comprising a light emitting element connected to the pixel driver,
wherein the circuit element layer comprises
a first transistor in the pixel driver, the first transistor comprising a first oxide semiconductor layer and a first gate,
a second transistor in the scan driver, the second transistor comprising a second gate and a second oxide semiconductor layer, and the second oxide semiconductor layer at a level different from a level of the first oxide semiconductor layer, and
an insulating layer between the first oxide semiconductor layer and the first gate, wherein the insulating layer comprises
a lower oxide layer,
an upper oxide layer on the lower oxide layer, and
a nitride layer between the lower oxide layer and the upper oxide layer, and wherein a hydrogen concentration of the nitride layer is higher than a hydrogen concentration of the upper oxide layer.

2. The electronic apparatus of claim 1, wherein a mobility of the second oxide semiconductor layer is higher than a mobility of the first oxide semiconductor layer.

3. The electronic apparatus of claim 2, wherein the second oxide semiconductor layer comprises indium tin gallium zinc oxide.

4. The electronic apparatus of claim 3, wherein the first oxide semiconductor layer comprises indium gallium zinc oxide or indium gallium oxide.

5. The electronic apparatus of claim 2, wherein the second oxide semiconductor layer contacts the upper oxide layer.

6. The electronic apparatus of claim 5, wherein a thickness of the upper oxide layer is less than a thickness of the nitride layer.

7. The electronic apparatus of claim 6, wherein the thickness of the upper oxide layer is 200 Å or less.

8. The electronic apparatus of claim 1, wherein the circuit element layer further comprises a plurality of lower patterns below the first oxide semiconductor layer.

9. The electronic apparatus of claim 8, wherein at least one of the plurality of lower patterns is connected to the first oxide semiconductor layer.

10. The electronic apparatus of claim 8, wherein at least one of the plurality of lower patterns in the pixel driver includes a capacitor.

11. The electronic apparatus of claim 8, further comprising:
a buffer layer between the plurality of lower patterns and the first oxide semiconductor layer,
wherein the buffer layer comprises
a lower buffer oxide layer,
an upper buffer oxide layer between the lower buffer oxide layer and the first oxide semiconductor layer, and
a buffer nitride layer between the lower buffer oxide layer and the upper buffer oxide layer.

12. The electronic apparatus of claim 11, wherein a thickness of the nitride layer is less than a thickness of the buffer nitride layer.

13. The electronic apparatus of claim 1, wherein the nitride layer comprises silicon nitride or silicon oxynitride.

14. An electronic apparatus comprising:
a display panel;
a processor configured to output data to the display panel; and
a power module configured to supply power to the processor,
wherein the display panel comprises
a light emitting element,
a pixel driver connected to the light emitting element, the pixel driver comprising
a first transistor,
a scan driver comprising a second transistor,
a gate line connecting the pixel driver to the scan driver,
a data line connected to the pixel driver, the data line insulated from and intersecting the gate line, and
a plurality of insulating layers,
wherein the plurality of insulating layers comprises
a first insulating layer below a first semiconductor layer of the first transistor, and
a second insulating layer between the first semiconductor layer and a first gate of the first transistor,
wherein each of the first insulating layer and the second insulating layer comprises
a lower oxide layer,
an upper oxide layer on the lower oxide layer, and
a nitride layer between the lower oxide layer and the upper oxide layer.

15. The electronic apparatus of claim 14, wherein
a second semiconductor layer of the second transistor is on the second insulating layer, and
the second semiconductor layer comprises a material having a higher mobility than a mobility of the first semiconductor layer.

16. The electronic apparatus of claim 15, wherein
the second semiconductor layer comprises indium tin gallium zinc oxide, and
the first semiconductor layer comprises indium gallium zinc oxide or indium gallium oxide.

17. The electronic apparatus of claim 15, further comprising:
a plurality of lower patterns below the first insulating layer,
wherein the first semiconductor layer is provided in a plurality of first semiconductor layers,
wherein at least one of the plurality of lower patterns is connected to the first semiconductor layer.

18. The electronic apparatus of claim 17, wherein
the upper oxide layer of the second insulating layer contacts the second semiconductor layer, and
a thickness of the upper oxide layer of the second insulating layer is 200 Å or less.

19. The electronic apparatus of claim 15, wherein
the plurality of insulating layers further comprise a gate insulating layer between the second semiconductor layer and a second gate of the second transistor, and
the gate insulating layer is between the second insulating layer and the first gate.

20. A method for manufacturing an electronic apparatus, the method comprising
forming a plurality of lower conductive patterns on a substrate;
stacking a first lower oxide layer, a first nitride layer, and a first upper oxide layer in sequence on the plurality of lower conductive patterns to form a first insulating layer;
forming a first semiconductor layer on the first insulating layer;
stacking a second lower oxide layer, a second nitride layer, and a second upper oxide layer in sequence on the first insulating layer to form a second insulating layer;
forming a second semiconductor layer on the second insulating layer;
forming a first gate overlapping the first semiconductor layer and a second gate overlapping the second semiconductor layer;
forming a third insulating layer covering the first gate and the second gate; and
forming a plurality of connection electrodes on the third insulating layer, and
wherein the forming of the second insulating layer comprises:
depositing a first oxide to form the second lower oxide layer;
depositing a nitride on the second lower oxide layer to form the second nitride layer; and
depositing a second oxide on the second nitride layer to form the second upper oxide layer.
